(19) United States
(12) Patent Application Publication
(10) Pub. No.: US 2025/0233110 A1
(43) Pub. Date: Jul. 17, 2025

(54) SEMICONDUCTOR PACKAGE

(71) Applicant: SAMSUNG ELECTRONICS CO., LTD., Suwon-si (KR)

(72) Inventors: Juhong SHIN, Suwon-si (KR); YOUNG LYONG KIM, Suwon-si (KR)

(73) Assignee: SAMSUNG ELECTRONICS CO., LTD., Suwon-si (KR)

(21) Appl. No.: 18/767,312

(22) Filed: Jul. 9, 2024

(30) Foreign Application Priority Data
Jan. 16, 2024 (KR) 10-2024-0006781

(51) Int. Cl. H01L 25/065; H01L 23/00; H01L 23/31; H01L 23/48; H01L 23/498; H01L 23/538; H01L 27/10; H01L 29/94; H10B 80/00

(52) U.S. Cl. CPC H01L 25/0652; H01L 23/3107; H01L 23/481; H01L 23/5383; H01L 24/24; H01L 24/73; H01L 23/49816; H01L 24/16; H01L 2224/24137; H01L 2224/24145; H01L 2224/73259; H10B 80/00; H10D 1/665; H10D 84/206

(57) ABSTRACT

A semiconductor package is provided and includes: a lower redistribution layer; a capacitor chip on the lower redistribution layer; an interposer chip on the lower redistribution layer, horizontally spaced apart from the capacitor chip, and connected to the lower redistribution layer; a mold layer surrounding the capacitor chip and the interposer chip; and an upper redistribution layer on a top surface of the mold layer and connected to the capacitor chip and the interposer chip. The capacitor chip includes a capacitor substrate and a capacitor device in the capacitor substrate, and the capacitor device includes: a top electrode pad; top electrodes on a bottom surface of the top electrode pad, a capacitor dielectric layer on the top electrodes with a uniform thickness; and a bottom electrode on the capacitor dielectric layer such as to commonly cover the top electrodes.

### CROSS-REFERENCE TO RELATED APPLICATIONS

This U.S. non-provisional patent application claims priority under 35 U.S.C. § 119 to Korean Patent Application No. 10-2024-0006781, filed on Jan. 16, 2024, in the Korean Intellectual Property Office, the entire contents of which are hereby incorporated by reference.

### BACKGROUND

### 1. Field

Embodiments of the present disclosure relate to a semiconductor package and a method of fabricating the same.

### 2. Brief Description of Background Art

With the recent advance in the electronics industry, the demand for high-performance, high-speed, and compact electronic components are increasing. To meet this demand, packaging technologies of mounting a plurality of semiconductor chips in a single package are being developed.

Recently, the demand for portable electronic devices has been rapidly increasing in the market, and thus, it is necessary to reduce sizes and weights of electronic components constituting the portable electronic devices. For this, it is necessary to develop packaging technologies of reducing a size and a weight of each component and of integrating a plurality of individual components in a single package.

In the case where the number of semiconductor chips in a semiconductor package increases, there are difficulties in placing many semiconductor chips in a printed circuit board. In order to alleviate these difficulties, a semiconductor package including an interposer, which is used to connect the semiconductor chips to each other, is being developed.

### SUMMARY

An embodiment of the present disclosure provides a semiconductor package with improved electrical characteristics and a method of fabricating the same.

An embodiment of the present disclosure provides a semiconductor package with a reduced size and a method of fabricating the same.

According to embodiments of the present disclosure, a semiconductor package is provided and includes: a lower redistribution layer; a capacitor chip on the lower redistribution layer; an interposer chip on the lower redistribution layer, horizontally spaced apart from the capacitor chip, and connected to the lower redistribution layer; a mold layer surrounding the capacitor chip and the interposer chip; and an upper redistribution layer on a top surface of the mold layer and connected to the capacitor chip and the interposer chip. The capacitor chip includes a capacitor substrate and a capacitor device in the capacitor substrate, and the capacitor device includes: a top electrode pad; top electrodes on a bottom surface of the top electrode pad, a capacitor dielectric layer on the top electrodes with a uniform thickness; and a bottom electrode on the capacitor dielectric layer such as to commonly cover the top electrodes.

According to embodiments of the present disclosure, a semiconductor package is provided and includes: an interposer substrate; and at least one semiconductor chip on the interposer substrate. The interposer substrate includes: a lower redistribution layer including a lower insulating pattern; a lower interconnection pattern in the lower insulating pattern; an upper redistribution layer on the lower redistribution layer, the upper redistribution layer including an upper insulating pattern and an upper interconnection pattern in the upper insulating pattern; and an interposer core structure between the lower redistribution layer and the upper redistribution layer. The interposer core structure includes a capacitor chip and an interposer chip, and the capacitor chip includes: a first electrode; a second electrode spaced apart from the first electrode; and a dielectric layer between the first electrode and the second electrode, wherein a top surface of the capacitor chip is exposed to an outside towards a top surface of the interposer core structure and is connected to the upper redistribution layer, and wherein a bottom surface of the capacitor chip is exposed to the outside towards a bottom surface of the interposer core structure and is connected to the lower redistribution layer.

According to embodiments of the present disclosure, a semiconductor package is provided and includes: an interposer substrate; an outer connection terminal on a bottom surface of the interposer substrate; a logic chip on the interposer substrate; and a chip stack on the interposer substrate and spaced apart from the logic chip. The interposer substrate includes: a lower redistribution layer; an upper redistribution layer on the lower redistribution layer; a capacitor chip between the lower redistribution layer and the upper redistribution layer; an interposer chip between the lower redistribution layer and the upper redistribution layer and horizontally spaced apart from the capacitor chip; and a mold layer surrounding the capacitor chip and the interposer chip. The interposer chip includes: at least one penetration via that penetrates the interposer chip and connects the interposer chip to the lower redistribution layer; an upper connection terminal on a top surface of the interposer chip and connects the interposer chip to the upper redistribution layer; and a lower connection terminal on a bottom surface of the interposer chip and connects the interposer chip to the lower redistribution layer, wherein the capacitor chip includes at least one capacitor device, and wherein the capacitor chip is coupled to the lower redistribution layer and the upper redistribution layer.

### BRIEF DESCRIPTION OF DRAWINGS

FIG. 1 is a section view illustrating a semiconductor package according to an embodiment of the present disclosure.

FIG. 2 is a section view illustrating a semiconductor package according to an embodiment of the present disclosure.

FIG. 3 is a section view illustrating a semiconductor package according to an embodiment of the present disclosure.

FIG. 4 is a section view illustrating a semiconductor package according to an embodiment of the present disclosure.

FIG. 5 is a section view illustrating a semiconductor package according to an embodiment of the present disclosure.

FIG. 6 is a section view illustrating a semiconductor package according to an embodiment of the present disclosure.

FIG. 7 is a sectional view illustrating an operation of a method of fabricating a semiconductor package according to an embodiment of the present disclosure.

FIG. 8 is a sectional view illustrating an operation of the method of fabricating the semiconductor package according to an embodiment of the present disclosure.

FIG. 9 is a sectional view illustrating an operation of the method of fabricating the semiconductor package according to an embodiment of the present disclosure.

FIG. 10 is a sectional view illustrating an operation of the method of fabricating the semiconductor package according to an embodiment of the present disclosure.

### DETAILED DESCRIPTION

Non-limiting example embodiments of the present disclosure will now be described more fully with reference to the accompanying drawings, in which example embodiments are shown.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

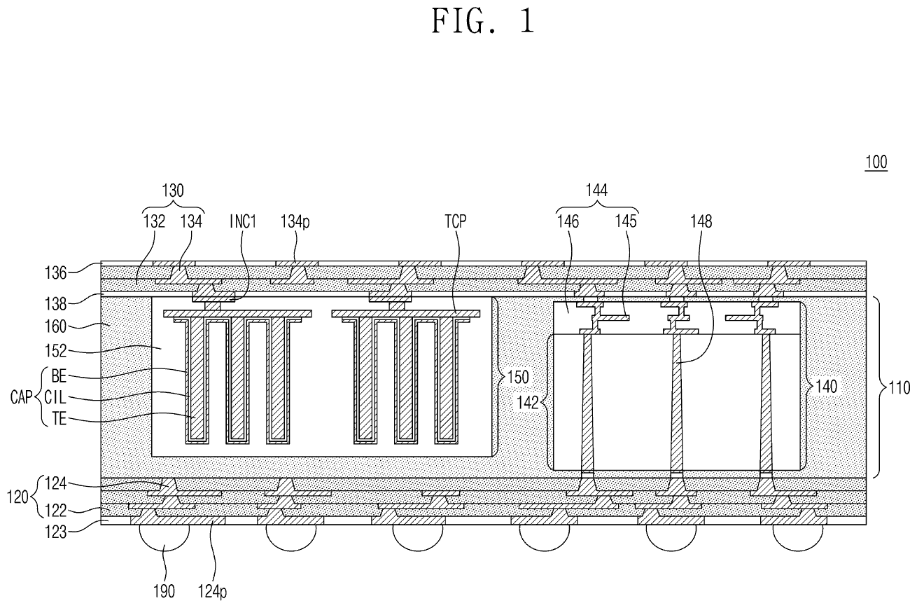

FIG. 1 is a sectional view illustrating a semiconductor package according to an embodiment of the present disclosure. Referring to FIG. 1, an interposer substrate 100 may be provided. The interposer substrate 100 may include an interposer core structure 110, a lower redistribution layer 120 provided on a bottom surface of the interposer core structure 110, and an upper redistribution layer 130 provided on a top surface of the interposer core structure 110.

The lower redistribution layer 120 may be disposed on the bottom surface of the interposer core structure 110. The lower redistribution layer 120 may cover the bottom surface of the interposer core structure 110. The lower redistribution layer 120 may be a redistribution layer for redistribution of the interposer substrate 100. The lower redistribution layer 120 may include one or more lower interconnection layers, which are sequentially stacked. Each of the lower interconnection layers may include a lower insulating pattern 122 and a lower interconnection pattern 124. The lower interconnection patterns 124, which are included in adjacent ones of the lower interconnection layers, may be electrically connected to each other. Hereinafter, the lower insulating pattern 122 and the lower interconnection pattern 124 will be described in detail with reference to one of the lower interconnection layers.

The lower insulating pattern 122 may be formed of or include at least one from among insulating polymers and photo-imageable polymers (PIDs). For example, the PID materials may include photoimageable polyimides, polybenzoxazole (PBO), phenol-based polymers, and benzocyclobutene-based polymers.

The lower interconnection pattern 124 may be provided on the lower insulating pattern 122. The lower interconnection pattern 124 may be provided on a bottom surface of the lower insulating pattern 122. The lower interconnection pattern 124 may include a protruding portion that is extended to a region on the bottom surface of the lower insulating pattern 122. The lower interconnection pattern 124 may be horizontally extended, on the bottom surface of the lower insulating pattern 122. On the bottom surface of the lower insulating pattern 122, the lower interconnection pattern 124 may be covered with the lower insulating pattern 122 of another lower interconnection layer thereunder. As described above, the lower interconnection pattern 124 may be a pad portion or a wire portion of the lower interconnection layer. That is, the lower interconnection pattern 124 may be an element that is used for horizontal redistribution in the lower redistribution layer 120. The lower interconnection pattern 124 may include a conductive material. For example, the lower interconnection pattern 124 may be formed of or include copper (Cu).

The lower interconnection pattern 124 may have a damascene structure. For example, the lower interconnection pattern 124 may include a via portion, which is extended upward from the top surface thereof. The via portion may be used to vertically connect the lower interconnection patterns 124, which are respectively included in adjacent ones of the lower interconnection layers, to each other. For example, the via portion may be extended from the top surface of the lower interconnection pattern 124 to penetrate the lower insulating pattern 122 and may be coupled to a bottom surface of the lower interconnection pattern 124 of another lower interconnection layer thereon. That is, a lower portion of the lower interconnection pattern 124, which is placed below the lower insulating pattern 122, may be a head portion, which is used as a horizontal wire or a pad, and the via portion of the lower interconnection pattern 124 may be a tail portion. The lower interconnection pattern 124 may have an inverted shape of the letter ‘T’.

A top surface of the lower interconnection pattern 124, which is placed in the uppermost one of the lower interconnection layers, may be exposed to the outside through a top surface of the uppermost one of the lower insulating patterns 122. The top surface of the uppermost one of the lower interconnection patterns 124 may be coplanar with the top surface of the uppermost one of the lower insulating patterns 122.

Lower substrate pads 124p may be disposed on a bottom surface of the lower interconnection pattern 124, which is placed in the lowermost one of the lower interconnection layers. According to embodiments, the lower substrate pads 124p may be protruding portions of the lower interconnection pattern 124, which are extended to a region below a bottom surface of the lower redistribution layer 120, or additional pads, which are placed below the lowermost one of the lower insulating patterns 122 and are connected to the lower interconnection pattern 124.

A lower substrate protection layer 123 may be disposed on the bottom surface of the lower redistribution layer 120. The lower substrate protection layer 123 may be provided to cover a bottom surface of the lowermost one of the lower redistribution layers 120 and to expose the lower substrate pads 124p. The lower substrate protection layer 123 may include at least one from among an insulating polymer (e.g., an epoxy-based polymer), an Ajinomoto Build-up Film (ABF), and organic or inorganic materials.

Outer terminals 190 may be provided below the lower redistribution layer 120. Each of the outer terminals 190 may be disposed on a bottom surface of a corresponding one of the lower substrate pads 124p. The outer terminals 190 may be electrically connected to the lower redistribution layer 120 through the lower substrate pads 124p. The outer terminals 190 may include solder balls or solder bumps.

The upper redistribution layer 130 may be provided on the top surface of the interposer core structure 110. The upper redistribution layer 130 may cover the top surface of the interposer core structure 110. The upper redistribution layer 130 may include one or more upper interconnection layers, which are sequentially stacked. Each of the upper interconnection layers may include an upper insulating pattern 132 and an upper interconnection pattern 134. The upper interconnection patterns 134, which are included in adjacent ones of the upper interconnection layers, may be electrically connected to each other. Hereinafter, the upper insulating pattern 132 and the upper interconnection pattern 134 will be described in detail with reference to one of the upper interconnection layers.

The upper insulating pattern 132 may be formed of or include at least one from among insulating polymers and photo-imageable polymers (PIDs). For example, the photoimageable polymers may include at least one from among photoimageable polyimide (PI), polybenzoxazole (PBO), phenol-based polymers, and benzocyclobutene-based polymers.

The upper interconnection pattern 134 may be provided on a bottom surface of the upper insulating pattern 132. The upper interconnection pattern 134 may include a protruding portion that is extended to a region on the bottom surface of the upper insulating pattern 132. The upper interconnection pattern 134 may be horizontally extended along the bottom surface of the upper insulating pattern 132. On the bottom surface of the upper insulating pattern 132, the upper interconnection pattern 134 may be covered with the upper insulating pattern 132 of another upper interconnection layer therebelow. As described above, the upper interconnection pattern 134 may be a pad portion or a wire portion of the upper interconnection layer. That is, the upper interconnection pattern 134 may be an element, which is used for horizontal redistribution in the upper redistribution layer 130. The upper interconnection pattern 134 may include a conductive material. For example, the upper interconnection pattern 134 may be formed of or include copper (Cu).

The upper interconnection pattern 134 may have a damascene structure. For example, the upper interconnection pattern 134 may have a via portion that is formed near a top surface thereof and has a protruding shape. The via portion may be used to vertically connect the upper interconnection patterns 134, which are respectively included in adjacent ones of the upper interconnection layers, to each other. For example, the via portion may be extended from the top surface of the upper interconnection pattern 134 to penetrate the upper insulating pattern 132 and may be connected to a bottom surface of the upper interconnection pattern 134 of another upper interconnection layer thereon. That is, a lower portion of the upper interconnection pattern 134, which is placed below the upper insulating pattern 132, may be a head portion, which is used as a horizontal wire or a pad, and the via portion of the upper interconnection pattern 134 may be a tail portion. The upper interconnection pattern 134 may have an inverted shape of letter ‘T’.

Head portions of the upper interconnection pattern 134, which are placed on the uppermost one of the upper interconnection layers, may be upper substrate pads 134p. Here, the upper substrate pads 134p may be protruding portions of the upper interconnection pattern 134, which are extended to a region on a top surface of the upper redistribution layer 130, or additional pads, which are placed on the uppermost one of the upper insulating patterns 132 and are connected to the upper interconnection pattern 134. An upper substrate protection layer 136 may be provided on the top surface of the upper redistribution layer 130. The upper substrate protection layer 136 may cover the uppermost one of the upper interconnection layers. The upper substrate protection layer 136 may be provided to cover the uppermost one of the upper insulating patterns 132 and surround the upper substrate pads 134p. The upper substrate pads 134p may be exposed to the outside of the upper substrate protection layer 136 near a top surface of the upper substrate protection layer 136. The upper substrate protection layer 136 may be formed of or include at least one from among insulating polymers and photoimageable polymers. For example, the upper substrate protection layer 136 may include at least one from among an insulating polymer (e.g., an epoxy-based polymer), an Ajinomoto Build-up Film (ABF), and organic or inorganic materials. In an embodiment, the upper substrate protection layer 136 may not be provided.

First substrate pads may be provided below a bottom surface of the lowermost one of the upper interconnection layers. The first substrate pads may be protruding portions of the upper interconnection pattern 134, which are extended to a region below the bottom surface of the lowermost one of the upper interconnection layers, or additional pads, which are placed below a bottom surface of the lowermost one of the upper insulating patterns 132 and are connected to the upper interconnection pattern 134. A first substrate protection layer 138 may be provided on a bottom surface of the upper redistribution layer 130. The first substrate protection layer 138 may cover the lowermost one of the upper interconnection layers. The first substrate protection layer 138 may be provided to cover the lowermost one of the upper insulating patterns 132 and to surround the first substrate pads. The first substrate pads may be exposed to the outside of the first substrate protection layer 138 near a bottom surface of the first substrate protection layer 138. The first substrate protection layer 138 may include an insulating polymer or a photoimageable polymer. For example, the first substrate protection layer 138 may include at least one from among an insulating polymer (e.g., an epoxy-based polymer), an Ajinomoto Build-up Film (ABF), and organic or inorganic materials. In an embodiment, the first substrate protection layer 138 may not be provided.

The interposer core structure 110 may be provided between the lower redistribution layer 120 and the upper redistribution layer 130. The interposer core structure 110, which is provided between the lower redistribution layer 120 and the upper redistribution layer 130, may electrically connect the lower redistribution layer 120 to the upper redistribution layer 130. The interposer core structure 110 may include an interposer chip 140 and a capacitor chip 150, which are provided therein, and a first mold layer 160 enclosing the interposer chip 140 and the capacitor chip 150.

The interposer chip 140 may include an interposer base layer 142, an interposer interconnection layer 144 on the interposer base layer 142, and interposer vias 148 in the interposer base layer 142. The interposer chip 140 may be provided in a face-up manner. The interposer chip 140 may have a front surface and a rear surface. In the present specification, the front surface may mean a surface of the interposer chip 140, on which the interconnection patterns of the interposer chip 140 are formed, and the rear surface may be another surface of the interposer chip 140 that is opposite to the front surface. The front surface of the interposer chip 140 may be an active surface. The interposer base layer 142 may include a semiconductor substrate. For example, the interposer base layer 142 may be a semiconductor substrate (e.g., a semiconductor wafer). The interposer base layer 142 may be a silicon substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate including an epitaxial film formed by a selective epitaxial growth (SEG) process. The interposer base layer 142 may be formed of or include at least one from among silicon (Si), germanium (Ge), silicon-germanium (SiGe), gallium arsenic (GaAs), indium gallium arsenic (InGaAs), and aluminum gallium arsenic (AlGaAs). The interposer chip 140 may include the interposer interconnection layer 144, which is provided on the front surface of the interposer chip 140. The interposer interconnection layer 144 may be provided on a top surface of the interposer base layer 142. The interposer interconnection layer 144 may be provided to be in contact with and cover the top surface of the interposer base layer 142. The interposer interconnection layer 144 may include an interposer insulating pattern 146, which is provided in the interposer interconnection layer 144, and an interposer conductive pattern 145, which is provided in the interposer insulating pattern 146. A portion of the interposer conductive pattern 145 may be exposed to the outside of the interposer insulating pattern 146 near a bottom surface of the interposer insulating pattern 146. The portion of the interposer conductive pattern 145, which is exposed to the outside of the interposer insulating pattern 146 near the bottom surface of the interposer insulating pattern 146, may be coplanar with the bottom surface of the interposer insulating pattern 146. A portion of the interposer conductive pattern 145 may be exposed to the outside of the interposer insulating pattern 146 near a top surface of the interposer insulating pattern 146. The interposer conductive pattern 145 may be formed of a conductive material (e.g., a metallic material). For example, the interposer conductive pattern 145 may be formed of or include copper (Cu). The interposer insulating pattern 146 may be formed of or include an oxide material (e.g., silicon oxide (SiOₓ)).

Portions of the interposer conductive pattern 145, which are exposed to the outside of the interposer insulating pattern 146 near the top surface of the interposer insulating pattern 146, may be upper interposer pads. Exposed surfaces of the upper interposer pads may be substantially coplanar with the top surface of the interposer insulating pattern 146. However, embodiments of the present disclosure are not limited to this example, and the upper interposer pads may include a portion protruding into the outside of the interposer insulating pattern 146.

Upper interposer connection terminals (e.g., solder balls or solder bumps) may be provided on a top surface of the interposer chip 140. An end of each of the upper interposer connection terminals may be in contact with a corresponding one of the upper interposer pads. The upper interposer connection terminals may be electrically connected to the interposer conductive pattern 145 through the upper interposer pads. An opposite end of each of the upper interposer connection terminals may be in contact with a corresponding one of first substrate pads. The interposer chip 140 may be electrically connected to the upper redistribution layer 130 using the upper interposer connection terminals. The upper interposer connection terminals may be provided between the bottom surface of the upper redistribution layer 130 and the top surface of the interposer chip 140 to connect the upper redistribution layer 130 to the interposer chip 140.

The interposer vias 148 may be provided to vertically penetrate the interposer base layer 142. Ends of the interposer vias 148 may be exposed to the outside of the interposer chip 140 near a bottom surface of the interposer chip 140. Here, the ends of the interposer vias 148 may be coplanar with the bottom surface of the interposer chip 140, and the ends of the interposer vias 148 and the bottom surface of the interposer chip 140 may be substantially flat. Opposite ends of the interposer vias 148 may be extended toward the top surface of the interposer chip 140 to be in contact with the interposer interconnection layer 144. The opposite ends of the interposer vias 148 may be in contact with a bottom surface of the interposer interconnection layer 144 and may be disposed at the same level as the level of the bottom surface of the interposer interconnection layer 144. The interposer vias 148 may be coupled to the interposer conductive pattern 145 of the interposer interconnection layer 144. In detail, the opposite ends of the interposer vias 148 may be in contact with the portion of the interposer conductive pattern 145, which is exposed to the outside through the bottom surface of the interposer interconnection layer 144.

The interposer chip 140 may further include lower interposer pads, which are provided on the bottom surface of the interposer chip 140. The lower interposer pads may be aligned to the interposer vias 148. Each of the lower interposer pads may be in contact with a bottom surface of a corresponding one of the interposer vias 148. The interposer vias 148 may be provided to connect the lower interposer pads to the interposer conductive pattern 145 of the interposer interconnection layer 144. The lower interposer pads may be electrically connected to the interposer conductive pattern 145 of the interposer interconnection layer 144 through the interposer vias 148.

Lower interposer connection terminals (e.g., solder bumps) may be provided on bottom surfaces of the lower interposer pads. However, embodiments of the present disclosure are not limited to this example, and the lower interposer connection terminals may include solder balls. Ends of the lower interposer connection terminals may be in contact with the lower interposer pads. The lower interposer connection terminals may be electrically connected to the interposer conductive pattern 145 in the interposer chip 140. The interposer chip 140 may be mounted on the lower redistribution layer 120 using the lower interposer connection terminals. Opposite ends of the lower interposer connection terminals may be in contact with the lower interconnection pattern 124 of the lower redistribution layer 120. In detail, the opposite ends of the lower interposer connection terminals may be electrically connected to the exposed top surface of the uppermost one of the lower interconnection patterns 124. The lower interposer connection terminals may be provided between the top surface of the lower redistribution layer 120 and the bottom surface of the interposer chip 140 to connect the lower redistribution layer 120 to the interposer chip 140. The interposer conductive pattern 145 may be electrically connected to the lower redistribution layer 120 through the interposer vias 148, the lower interposer pads, and the lower interposer connection terminals.

The interposer chip 140 may not include an additional integrated circuit. That is, the interposer chip 140 may be configured for easy interconnection between the upper redistribution layer 130 and the lower redistribution layer 120. Alternatively, the interposer chip 140 may include a specific integrated circuit. In this case, the integrated circuit may be formed on the front surface of the interposer chip 140. The integrated circuit may be formed on the top surface of the interposer base layer 142. Here, the interposer conductive pattern 145 may cover the integrated circuit, on the top surface of the interposer base layer 142. The interposer conductive pattern 145 may be electrically connected to the integrated circuit. The integrated circuit may include a ground circuit or a power circuit. Alternatively, the integrated circuit may include a memory circuit, a logic circuit, or an integrated circuit for wireless communication.

According to embodiments, a chip protection layer may be provided to cover a bottom surface of the interposer base layer 142. In an embodiment, the chip protection layer may be a portion of the bottom surface of the interposer base layer 142. For example, the chip protection layer may be a layer that is formed by oxidizing a portion of the bottom surface of the interposer base layer 142.

The interposer core structure 110 may include the capacitor chip 150, which is provided in the interposer core structure 110 and is horizontally spaced apart from the interposer chip 140. The capacitor chip 150 may be disposed on the bottom surface of the upper redistribution layer 130. The capacitor chip 150 may be disposed between the lower redistribution layer 120 and the upper redistribution layer 130. A height (or thickness) of the capacitor chip 150 may be smaller than a distance from the top surface of the lower redistribution layer 120 to the bottom surface of the upper redistribution layer 130. The height (or thickness) of the capacitor chip 150 may be smaller than a height (or thickness) of the interposer chip 140. A bottom surface of the capacitor chip 150 may be spaced apart from the lower redistribution layer 120. The capacitor chip 150 may include top electrode pads TCP, first signal lines INC1, a capacitor substrate 152, and at least one capacitor device CAP. Hereinafter, for convenience in description, the following description will be given based on one capacitor device CAP provided in the capacitor chip 150, but such description may be applied to other capacitor devices CAP.

The capacitor chip 150 may include a multilayer ceramic (MLC) capacitor device. However, embodiments of the present disclosure are not limited to this example, and various kinds of capacitor devices may be used as the capacitor chip 150. The capacitor chip 150 may include the capacitor substrate 152 and the first signal line INC1 in the capacitor substrate 152. The capacitor substrate 152 may include a semiconductor substrate. For example, the capacitor substrate 152 may be a semiconductor substrate (e.g., a semiconductor wafer). The capacitor substrate 152 may be a silicon substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate including an epitaxial film formed by a selective epitaxial growth (SEG) process. The capacitor substrate 152 may be formed of or include at least one from among silicon (Si), germanium (Ge), silicon-germanium (SiGe), gallium arsenic (GaAs), indium gallium arsenic (InGaAs), and aluminum gallium arsenic (AlGaAs). The first signal line INC1 may be placed in the capacitor substrate 152. A top surface of the first signal line INC1 may be exposed to the outside of the capacitor chip 150. The top surface of the first signal line INC1 may be coplanar with a top surface of the capacitor substrate 152. The exposed top surface of the first signal line INC1 may be in contact with the upper redistribution layer 130. In detail, the first signal line INC1 may be in contact with the first substrate pads. The first signal line INC1 may be electrically connected to the upper redistribution layer 130 through the first substrate pads. The first signal line INC1 may be formed of or include at least one from among various metallic materials (e.g., copper (Cu), aluminum (Al), and/or nickel (Ni)).

The top electrode pad TCP may be provided in the capacitor substrate 152. The top electrode pad TCP may be disposed on a bottom surface of the first signal line INC1. The top electrode pad TCP may be connected to the first signal line INC1 through a via plug, which is provided below the bottom surface of the first signal line INC1, as shown in FIG. 1. The top electrode pad TCP may be a plate-shaped structure.

The capacitor device CAP may be provided on a bottom surface of the top electrode pad TCP. The capacitor device CAP may be in contact with the top electrode pad TCP. The capacitor device CAP may be electrically connected to the upper redistribution layer 130 through the top electrode pad TCP. The capacitor device CAP may include a bottom electrode BE, a top electrode TE, and a capacitor dielectric layer CIL between the bottom electrode BE and the top electrode TE.

In an embodiment, a plurality of top electrodes TE may be provided. Each of the top electrodes TE may have a pillar-shaped pattern, which is vertically extended from the top electrode pad TCP. The top electrodes TE may be provided to have a uniform width and a uniform height. Bottom surfaces of the top electrodes TE may be substantially coplanar with each other. The top electrodes TE may be disposed in various shapes. For example, the top electrodes TE may be spaced apart from each other, on the bottom surface of the top electrode pad TCP. Alternatively, the top electrodes TE may be arranged in a zigzag or honeycomb shape. Since the top electrodes TE are arranged in the zigzag or honeycomb shape, it may be possible to easily increase a diameter of the top electrode TE and an integration density of the top electrodes TE. The top electrodes TE may be electrically connected in common to the top electrode pad TCP. The top electrodes TE may be in direct contact with and connected to the bottom surface of the top electrode pad TCP. However, embodiments of the present disclosure are not limited to this example, and the top electrodes TE may be connected to the top electrode pad TCP through via plugs, which are provided on top surfaces of the top electrodes TE.

The capacitor dielectric layer CIL and the bottom electrode BE may be sequentially placed on the top electrodes TE. The capacitor dielectric layer CIL and the bottom electrode BE may cover the bottom and side surfaces of the top electrodes TE. The capacitor dielectric layer CIL may be placed between the top electrodes TE and the bottom electrode BE. The capacitor dielectric layer CIL may be provided to cover the top electrodes TE with a uniform thickness and to fill a space between the top electrodes TE and the bottom electrode BE. The capacitor dielectric layer CIL may cover the bottom and side surfaces of the top electrodes TE and an exposed bottom surface of the top electrode pad TCP between the top electrodes TE. The capacitor dielectric layer CIL may be extended from an outer side surface of the top electrode TE to the bottom surface of the top electrode pad TCP to cover a portion of the bottom surface of the top electrode pad TCP. The thickness of the capacitor dielectric layer CIL may be smaller than thicknesses of the top electrode TE and the bottom electrode BE. The capacitor dielectric layer CIL may be formed of or include at least one from among metal oxides (e.g., HfO₂, ZrO₂, Al₂O₃, La₂O₃, Ta₂O₃, and TiO₂) and piezoelectric materials (e.g., SrTiO₃, (Ba,Sr) TiO₃, BaTiO₃, PZT, and PLZT) with a perovskite structure and may be provided in a single-or multi-layered structure.

The bottom electrode BE may be placed on the capacitor dielectric layer CIL. The bottom electrode BE may be provided to conformally cover the capacitor dielectric layer CIL. Alternatively, the bottom electrode BE may be provided on the capacitor dielectric layer CIL to fill a space between the top electrodes TE. In an embodiment, each bottom electrode BE may be provided to face a plurality of top electrodes TE. That is, the top electrodes TE may share one bottom electrode BE. The top electrodes TE and the bottom electrode BE may be formed of or include at least one from among high melting point metals (e.g., cobalt, titanium, nickel, tungsten, and molybdenum) and/or metal nitrides (e.g., titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), and tungsten nitride (WN)).

FIG. 1 illustrates an example, in which the first signal line INC1 is in contact with and electrically connected to the upper interconnection pattern 134 of the upper redistribution layer 130, but embodiments of the present disclosure are not limited to this example. In an embodiment, the first signal line INC1 may not be provided. In this case, the top electrode pad TCP may be exposed to the outside of the capacitor chip 150 near the top surface of the capacitor chip 150 and may be coupled to the upper interconnection pattern 134. In addition, the capacitor chip 150 and the upper redistribution layer 130 may not be in contact with each other. For example, upper chip connection terminals (e.g., solder balls or solder bumps) may be provided on the top surface of the capacitor chip 150. The upper chip connection terminals may be disposed between the capacitor chip 150 and the upper redistribution layer 130 to connect the upper redistribution layer 130 to the capacitor chip 150. Ends of the upper chip connection terminals may be in contact with the first signal line INC1. The upper interposer connection terminals may be electrically connected to the capacitor device CAP through the first signal line INC1. Opposite ends of the upper chip connection terminals may be in contact with the first substrate pads of the upper redistribution layer 130. The capacitor chip 150 may be electrically connected to the upper redistribution layer 130 using the upper chip connection terminals.

The first mold layer 160 may be provided on the lower redistribution layer 120. The first mold layer 160 may be provided to cover the top surface of the lower redistribution layer 120 and surround the interposer chip 140 and the capacitor chip 150. The first mold layer 160 may be provided to fill a space between the interposer chip 140 and the capacitor chip 150. The first mold layer 160 may be provided to cover the interposer chip 140 and surround the upper interposer connection terminals. A top surface of the first mold layer 160 may be coplanar with the bottom surface of the first substrate protection layer 138 of the upper redistribution layer 130 and the top surface of the capacitor chip 150. The first mold layer 160 may cover the bottom surface of the capacitor chip 150. The first mold layer 160 may be provided to fill a space between the bottom surface of the capacitor chip 150 and the lower redistribution layer 120. The first mold layer 160 may be provided to fill a space between the bottom surface of the interposer chip 140 and the lower redistribution layer 120. The first mold layer 160 may be provided to surround the lower interposer connection terminals of the interposer chip 140. The first mold layer 160 may include an insulating material. For example, the first mold layer 160 may be formed of or include an epoxy molding compound (EMC).

According to embodiments, the interposer substrate 100 may include a connection member, which is provided near the interposer chip 140 and the capacitor chip 150 and is used to connect the lower redistribution layer 120 to the upper redistribution layer 130. The connection member may be a metal post. The metal post may be disposed between the lower redistribution layer 120 and the upper redistribution layer 130. The metal post may be horizontally spaced apart from the interposer chip 140 and the capacitor chip 150. The metal post may be provided to vertically penetrate the first mold layer 160. An end of the metal post may be connected to the first substrate pad of the upper redistribution layer 130. An opposite end of the metal post may be connected to the lower interconnection pattern 124 of the lower redistribution layer 120. That is, the lower redistribution layer 120 and the upper redistribution layer 130 may be electrically connected to each other through the metal post. A width of the metal post may increase as a distance from the lower redistribution layer 120 increases. That is, the metal post may have a tapered shape in a specific direction.

Alternatively, the metal post may be a pillar pattern whose width is substantially constant regardless of a position in a vertical direction. According to embodiments, a seed layer and a barrier layer may be provided between the metal post and the first mold layer 160. For example, the seed layer and the barrier layer may cover bottom or side surfaces of the metal post. In an embodiment, a plurality of metal posts may be provided. The metal post may be formed of or include a metallic material. The metal material may include copper (Cu), aluminum (Al), silver (Ag), tin (Sn), gold (Au), nickel (Ni), lead (Pb), titanium (Ti), or alloys thereof.

FIG. 1 illustrates the capacitor chip 150, which is in contact with the upper redistribution layer 130 and has a bottom surface that is spaced apart from the lower redistribution layer 120, but embodiments of the present disclosure are not limited to this example.

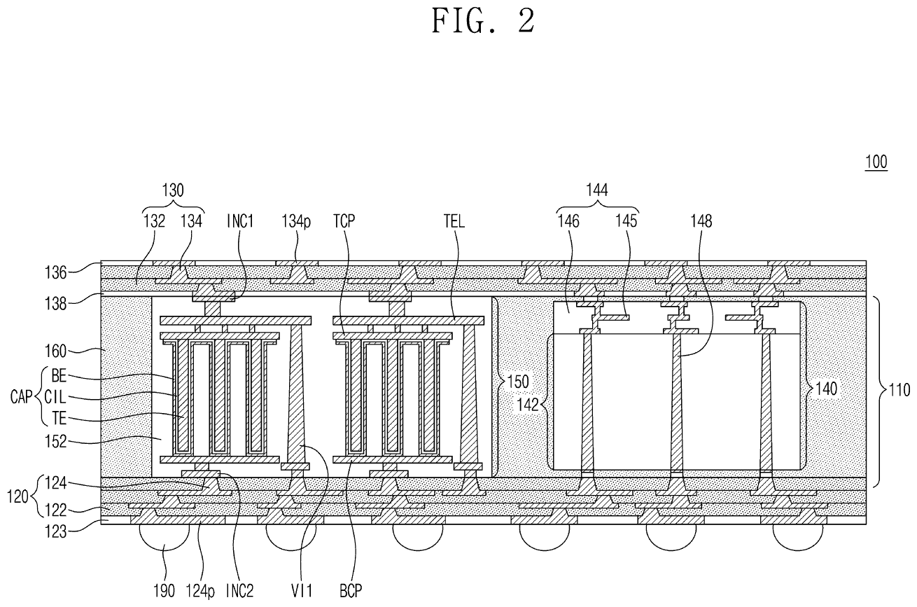

FIG. 2 is a sectional view illustrating a semiconductor package according to an embodiment of the present disclosure. Referring to FIG. 2, the interposer substrate 100 may be provided to have a structure similar to the structure of FIG. 1. In an embodiment, the interposer substrate 100 may include the lower redistribution layer 120, the upper redistribution layer 130, and the interposer core structure 110. However, unlike the structure of FIG. 1, a height (or thickness) of the capacitor chip 150 may be equal to a distance between the lower redistribution layer 120 and the upper redistribution layer 130. A height (or thickness) of the capacitor chip 150 may be larger than a height (or thickness) of the interposer chip 140. The capacitor chip 150 may be coupled to the upper redistribution layer 130 and the lower redistribution layer 120. A top surface of the capacitor chip 150 may be coplanar with the bottom surface of the first substrate protection layer 138 of the upper redistribution layer 130. The bottom surface of the capacitor chip 150 may be coplanar with the top surface of the lower redistribution layer 120. Here, the capacitor device CAP may further include a top electrode line TEL, a first via VI1, a bottom electrode pad BCP, and second signal lines INC2. Hereinafter, for convenience in description, the following description will be given based on one capacitor device CAP provided in the capacitor chip 150.

The top electrode line TEL may be provided on a top surface of the top electrode pad TCP. The top electrode line TEL may be a plate-shaped structure. A width of the top electrode line TEL may be larger than a width of the top electrode pad TCP. Here, each of the widths of the top electrode line TEL and the top electrode pad TCP may be a length measured in a direction parallel to the top surface of the lower redistribution layer 120. The top electrode line TEL may be placed in the capacitor substrate 152. The top electrode line TEL may be placed between the top electrode pad TCP and the first signal line INC1. The top electrode line TEL may be connected to the top electrode pad TCP and the first signal line INC1 through via plugs. The top electrode line TEL may be electrically connected to the upper redistribution layer 130 through the first signal line INC1. The top electrode line TEL may be electrically connected to the capacitor device CAP through the top electrode pad TCP. The first via VI1 may be extended from a bottom surface of the top electrode line TEL to penetrate the capacitor substrate 152. The lower redistribution layer 120, the upper redistribution layer 130, and the capacitor device CAP may be connected to each other through the first via VI1 and the top electrode line TEL. That is, the upper redistribution layer 130 and the lower redistribution layer 120 may be electrically connected to each other through the top electrode line TEL and the first via VI1. The first via VI1 may have a bottom surface, which is exposed to the outside of the capacitor substrate 152 near a bottom surface of the capacitor substrate 152. In an embodiment, the top electrode line TEL and the first via VII may not be provided.

The bottom electrode pad BCP may be disposed on the bottom surface of the top electrodes TE. A top surface of the bottom electrode pad BCP may be in contact with the bottom electrode BE. The bottom electrode BE may be electrically connected to the bottom electrode pad BCP. The bottom electrode pad BCP may be a plate-shaped structure. The second signal line INC2 may be provided on a bottom surface of the bottom electrode pad BCP. The second signal line INC2 may be electrically connected to the bottom electrode pad BCP through a via plug. The second signal line INC2 may be exposed to the outside of the capacitor chip 150. A bottom surface of the second signal line INC2 may be coplanar with the bottom surface of the capacitor chip 150. The second signal line INC2 may be electrically connected to the lower redistribution layer 120. In detail, the second signal line INC2 may be in contact with a portion of the lower interconnection pattern 124, which is exposed to the outside of the lower redistribution layer 120 near the top surface of the lower redistribution layer 120. The second signal line INC2 may be formed of or include at least one from among various metallic materials (e.g., copper (Cu), aluminum (Al), and/or nickel (Ni)).

According to embodiments, upper seed patterns may be provided on the bottom surfaces of the first substrate pads. Hereinafter, for the sake of brevity, the following description will be given based on one upper seed pattern and one first signal line INC1, but such description may be applied other upper seed patterns and first signal lines INC1. The upper seed pattern may cover a bottom surface of a corresponding first substrate pad. A top surface of the upper seed pattern may be in contact with the bottom surface of the first substrate pad, and a bottom surface of the upper seed pattern may be in contact with the top surface of the capacitor chip 150. A level of the bottom surface of the upper seed pattern may be substantially equal to a level of the bottom surface of the upper redistribution layer 130. The upper seed pattern may be formed of or include a conductive material different from a material of the upper interconnection pattern 134. In an embodiment, the upper seed pattern may be formed of or include copper, titanium, and/or alloys thereof. The upper seed pattern may be used to connect the upper interconnection pattern 134 to the first signal line INC1. The seed pattern and the first signal line INC1 may form an inter-metal hybrid bonding structure. In the present specification, the hybrid bonding structure may mean a bonding structure that is formed by two materials, which are of the same kind and are fused at an interface therebetween. For example, the upper seed pattern and the first signal line INC1, which are bonded to each other, may have a continuous structure, and an interface between the first signal line INC1 and the upper seed pattern may not be visible or observable. For example, the upper seed pattern and the first signal line INC1 may be formed of the same material, and there may be no interface between the upper seed pattern and the first signal line INC1. However, embodiments of the present disclosure are not limited to this example. The upper seed pattern and the first signal line INC1 may have different structures from each other, and in this case, the interface between the upper seed pattern and the first signal line INC1 may be visible. The upper interconnection pattern 134 may be electrically connected to the capacitor device CAP through the upper seed pattern and the first signal line INC1.

According to embodiments, a lower seed pattern may be provided on a top surface of the uppermost one of the lower interconnection patterns 124. The lower seed pattern may cover the top surface of the uppermost one of the lower interconnection patterns 124. A bottom surface of the lower seed pattern may be in contact with the top surface of the uppermost one of the lower interconnection patterns 124, and the bottom surface of the upper seed pattern may be in contact with the bottom surface of the capacitor chip 150. A level of a top surface of the lower seed pattern may be substantially equal to a level of the top surface of the lower redistribution layer 120. The lower seed pattern may include a conductive material different from a material of the lower interconnection pattern 124. For example, the lower seed pattern may be formed of or include at least one from among copper, titanium, and/or alloys thereof. The lower seed pattern may be used to connect the lower interconnection pattern 124 to the second signal line INC2. The lower seed pattern and the second signal line INC2 may form an inter-metal hybrid bonding structure. The lower seed pattern and the second signal line INC2, which are bonded to each other, may have a continuous structure, and in this case, there may be no interface between the second signal line INC2 and the lower seed pattern. For example, the lower seed pattern and the second signal line INC2 may be formed of the same material, and there may be no interface between the lower seed pattern and the second signal line INC2. However, embodiments of the present disclosure are not limited to this example. The lower seed pattern and the second signal line INC2 may be provided as distinct elements, and in this case, there may be a visible or observable interface between the lower seed pattern and the second signal line INC2. The lower interconnection pattern 124 may be electrically connected to the capacitor device CAP through the lower seed pattern and the second signal line INC2.

FIG. 2 illustrates an example, in which the second signal line INC2 of the capacitor chip 150 is in contact with the lower interconnection pattern 124 and the capacitor chip 150 and the lower redistribution layer 120 are connected to each other, but embodiments of the present disclosure are not limited to this example. Lower chip connection terminals (e.g., solder balls or solder bumps) may be provided on the bottom surface of the capacitor chip 150. The lower chip connection terminals may be in contact with the bottom surface of the bottom electrode pad BCP. The lower chip connection terminals may be electrically connected to the capacitor device CAP in the capacitor chip 150 through the bottom electrode pad BCP. The capacitor chip 150 may be electrically connected to the lower redistribution layer 120 using the lower chip connection terminals. The lower chip connection terminals may be provided between the top surface of the lower redistribution layer 120 and the bottom surface of the capacitor chip 150 to connect the lower redistribution layer 120 to the capacitor chip 150.

In addition, FIG. 2 illustrates an example, in which the first signal lines INC1 and the second signal lines INC2 are provided to electrically connect the capacitor device CAP to the upper redistribution layer 130 and the lower redistribution layer 120, but embodiments of the present disclosure are not limited to this example. In an embodiment, the first signal line INC1 may not be provided. Here, the top electrode line TEL may be exposed to the outside of the capacitor chip 150 near the top surface of the capacitor chip 150. The top electrode line TEL may be coupled to the upper redistribution layer 130. In an embodiment, the second signal line INC2 may not be provided. Here, the bottom electrode pad BCP may be exposed to the outside of the capacitor chip 150 near the bottom surface of the capacitor chip 150. Here, the bottom electrode pad BCP may be exposed to the outside of the capacitor chip 150 near the bottom surface of the capacitor chip 150 and may be coupled to the lower redistribution layer 120.

FIG. 1 illustrates an example, in which the metal post is used as the connection member, which connects the lower redistribution layer 120 to the upper redistribution layer 130 at a side of the interposer chip 140 and the capacitor chip 150, but embodiments of the present disclosure are not limited to this example. The connection member may be a connection substrate.

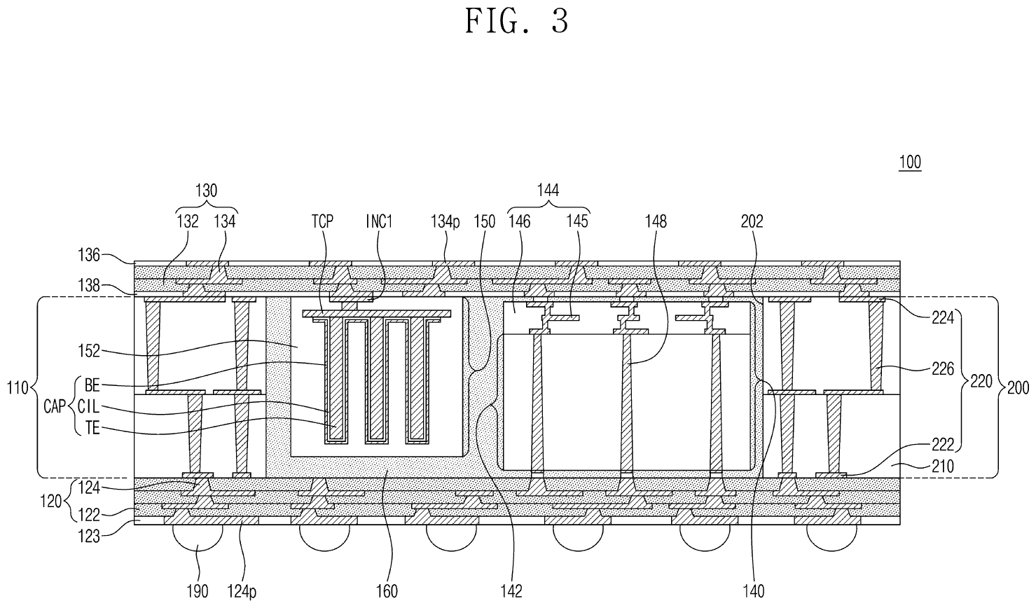

FIG. 3 is a sectional view illustrating a semiconductor package according to an embodiment of the present disclosure. Referring to FIG. 3, the interposer substrate 100 may be provided to have a structure similar to the structure of FIG. 1. For example, the interposer substrate 100 may include the lower redistribution layer 120, the upper redistribution layer 130 and the interposer core structure 110. However, a connection substrate 200 may be disposed on the lower redistribution layer 120, unlike the structure of FIG. 1. The connection substrate 200 may be provided as a connection member, instead of the metal post of FIG. 1. A thickness of the connection substrate 200 may be equal to a distance between the lower redistribution layer 120 and the upper redistribution layer 130. A top surface of the connection substrate 200 may be in contact with the bottom surface of the upper redistribution layer 130. A bottom surface of the connection substrate 200 may be in contact with the top surface of the lower redistribution layer 120. The connection substrate 200 may have an opening 202, which is provided to penetrate the same. For example, the opening 202 may be provided in the form of an open hole from the top surface of the connection substrate 200 to the bottom surface of the connection substrate 200. The connection substrate 200 may include a base layer 210 and a conductive portion 220, which is an interconnection pattern provided in the base layer 210. The conductive portion 220 may be an interconnection structure that is used to vertically connect the lower redistribution layer 120 to the upper redistribution layer 130. In an embodiment, the base layer 210 may be formed of or include silicon oxide. The conductive portion 220 may be spaced apart from the opening 202. The conductive portion 220 may be disposed in an outer region of the connection substrate 200, compared with the opening 202. The conductive portion 220 may include lower pads 222, upper pads 224, and connection substrate vias 226. The lower pads 222 may be disposed in a lower portion of the connection substrate 200. FIG. 3 illustrates an example, in which the lower pads 222 of the connection substrate 200 are directly coupled to the lower redistribution layer 120, but embodiments of the present disclosure are not limited to this example. The connection substrate 200 may be mounted on the lower redistribution layer 120 using solder balls or solder bumps, which are provided on the lower pads 222. Hereinafter, the present disclosure will be described further with reference to the embodiment of FIG. 3.

The upper pads 224 may be exposed to the outside of the connection substrate 200 near the top surface of the connection substrate 200. The upper pads 224 may have top surfaces that are coplanar with the top surface of the connection substrate 200. Alternatively, according to an example embodiment, the upper pad 224 may include a protruding portion that is extended to a region on a top surface of the base layer 210. The upper pads 224 may be electrically connected to the upper interconnection pattern 134 of the upper redistribution layer 130. The connection substrate vias 226 may be provided to penetrate the base layer 210 and to electrically connect the lower pads 222 to the upper pads 224.

The lower pads 222 may be disposed on the bottom surface of the connection substrate 200. The lower pads 222 may be buried in the base layer 210, and bottom surfaces of the lower pads 222 may be coplanar with the bottom surface of the connection substrate 200. The base layer 210 may be formed of or include at least one of polymer materials. For example, the base layer 210 may be formed of or include at least one from among insulating polymers and photoimageable polymers (e.g., photoimageable dielectric (PID)). In an embodiment, the photoimageable polymers may include photoimageable polyimide, polybenzoxazole (PBO), phenol-based polymers, or benzocyclobutene-based polymers. Alternatively, the base layer 210 may include an insulating material. For example, the base layer 210 may be formed of or include at least one from among silicon oxide (SiO), silicon nitride (SiNx), silicon oxynitride (SiON), and insulating polymer. The upper pads 224, the lower pads 222, and the connection substrate vias 226 may be formed of or include at least one from among metallic and conductive materials (e.g., copper (Cu)).

The interposer chip 140 and the capacitor chip 150 may be disposed in the opening 202 of the connection substrate 200. Here, the interposer chip 140 and the capacitor chip 150 may be provided to have the same or similar features as the features in the embodiment of FIG. 1. Each of the interposer chip 140 and the capacitor chip 150 may be spaced apart from an inner surface of the opening 202. The interposer chip 140 and the capacitor chip 150 may be spaced apart from each other, in the opening 202 of the connection substrate 200. The top surface of the capacitor chip 150 may be in contact with the bottom surface of the upper redistribution layer 130. The interposer chip 140 may be electrically connected to the upper and lower redistribution layers through the upper and lower interposer connection terminals. The first mold layer 160 may be disposed in the opening 202 of the connection substrate 200, on the lower redistribution layer 120. The first mold layer 160 may be provided to surround the interposer chip 140 and the capacitor chip 150 and to fill a space between the interposer and chip 140 and the capacitor chip 150. The first mold layer 160 may be provided to fill spaces between an outer side surface of the capacitor chip 150 and the inner surface of the opening 202 and between an outer side surface of the interposer chip 140 and the inner surface of the opening 202. The top surface of the first mold layer 160 may be coplanar with the top surface of the connection substrate 200. The first mold layer 160 may be provided to fill spaces between the bottom surface of the capacitor chip 150 and the lower redistribution layer 120 and between the bottom surface of the interposer chip 140 and the lower redistribution layer 120.

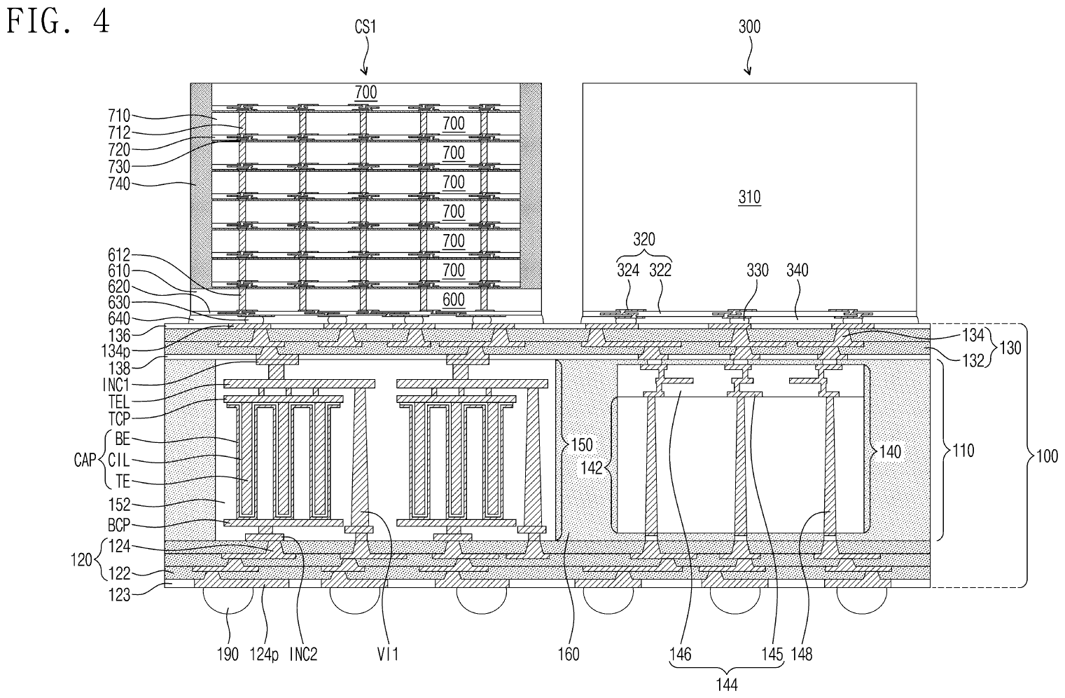

FIG. 4 is a sectional view illustrating a semiconductor package according to an embodiment of the present disclosure. Referring to FIG. 4, the interposer substrate 100 may be provided. Here, the interposer substrate 100 may correspond to the interposer substrate 100 described with reference to FIG. 2. For example, the interposer substrate 100 may include the interposer chip 140 and the capacitor chip 150, and the capacitor chip 150 may be connected to the upper redistribution layer 130 and the lower redistribution layer 120.

A first semiconductor chip 300 may be disposed on a top surface of the interposer substrate 100. The first semiconductor chip 300 may be vertically spaced apart from the interposer chip 140, when viewed in a plan view. That is, depending on a width of the interposer chip 140, the first semiconductor chip 300 may be fully or partially overlapped with the interposer chip 140 in a vertical direction. The first semiconductor chip 300 may be horizontally spaced apart from the capacitor chip 150, when viewed in a plan view. That is, the first semiconductor chip 300 may not be vertically overlapped with the capacitor chip 150. The first semiconductor chip 300 may be provided on the interposer substrate 100 in a face-down manner. A bottom surface of the first semiconductor chip 300 may be an active surface. The first semiconductor chip 300 may include a first semiconductor substrate 310. The first semiconductor substrate 310 may include a semiconductor material. In an embodiment, the first semiconductor substrate 310 may be formed of or include silicon (Si). An integrated device or integrated circuits may be formed on a bottom surface of the first semiconductor substrate 310. The integrated device or the integrated circuits may include a logic circuit. That is, the first semiconductor chip 300 may be a logic chip.

A first interconnection layer 320 may be provided on the bottom surface of the first semiconductor substrate 310. The first interconnection layer 320 may have a first insulating pattern 322 and a first interconnection pattern 324 provided in the first insulating pattern 322. The first insulating pattern 322 may be provided on the bottom surface of the first semiconductor chip 300 to cover the integrated device or the integrated circuits. The first interconnection pattern 324 may be coupled to the integrated device or the integrated circuits, which are formed on the first semiconductor substrate 310.

The first semiconductor chip 300 may be mounted on the interposer substrate 100. For example, the first semiconductor chip 300 may be electrically connected to the upper redistribution layer 130 through first connection terminals 330. The first connection terminals 330 may be provided between the upper substrate pads 134p and first chip pads, which are provided on the bottom surface of the first semiconductor chip 300. A bottom surface of each of the first connection terminals 330 may be in contact with a top surface of a corresponding one of the upper substrate pads 134p. A top surface of each of the first connection terminals 330 may be in contact with a bottom surface of a corresponding one of the first chip pads. Here, the first chip pads may be protruding portions of the first interconnection pattern 324, which are extended from the first insulating pattern 322 of the first interconnection layer 320, or additional pads, which are disposed on the first insulating pattern 322 of the first interconnection layer 320 and are connected to the first interconnection pattern 324. Since the first semiconductor chip 300 is mounted on the interposer substrate 100 using the first connection terminals 330, the bottom surface of the first semiconductor chip 300 may be spaced apart from the interposer substrate 100.

A first under-fill layer 340 may be provided between the top surface of the interposer substrate 100 and the bottom surface of the first semiconductor chip 300. The first under-fill layer 340 may be provided to fill a space between the interposer substrate 100 and the first semiconductor chip 300 and to surround the first chip pads and the first connection terminals 330.

A first chip stack CS1 may be provided on the interposer substrate 100. The first chip stack CS1 may be horizontally spaced apart from the first semiconductor chip 300, on the interposer substrate 100. The first chip stack CS1 may be vertically spaced apart from the capacitor chip 150, when viewed in a plan view. That is, depending on a width of the capacitor chip 150, the first chip stack CS1 may be fully or partially overlapped with the capacitor chip 150 in a vertical direction. The first chip stack CS1 may be horizontally spaced apart from the interposer chip 140, when viewed in a plan view. That is, the first chip stack CS1 may not be vertically overlapped with the interposer chip 140. The first chip stack CS1 may include a base chip 600, second semiconductor chips 700 stacked on the base chip 600, and a second mold layer 740 enclosing the second semiconductor chips 700. Hereinafter, the structure of the first chip stack CS1 will be described in more detail below.

The base chip 600 may include a base substrate 610. The base substrate 610 may be a semiconductor substrate. For example, the base substrate 610 may be a wafer-level semiconductor substrate, which is formed of a semiconductor material (e.g., silicon (Si)). A bottom surface of the base chip 600 may be an active surface. In detail, an integrated device or integrated circuits may be formed on the bottom surface of the base substrate 610. For example, the integrated device or the integrated circuits may include a memory circuit. That is, the base chip 600 may be a memory chip (e.g., a dynamic random access memory (DRAM), static random access memory (SRAM), magnetoresistive random access memory (MRAM), or FLASH memory chip). Alternatively, the integrated device or the integrated circuits may include a logic circuit. In this case, the base chip 600 may be a logic chip.

The base chip 600 may include a base circuit layer 620 and a base penetration via 612. The base circuit layer 620 may be provided on a bottom surface (e.g., of the base substrate 610) of the base chip 600. The base circuit layer 620 may include the integrated device or the integrated circuit. The base penetration via 612 may be provided to penetrate the base chip 600 in a direction perpendicular to the top surface of the interposer substrate 100. The base penetration via 612 and the base circuit layer 620 may be electrically connected to each other.

The base chip 600 may further include a protection layer and second connection terminals 630. According to embodiments, the protection layer may be disposed on the bottom surface of the base chip 600 to cover the base circuit layer 620. The protection layer may be formed of or include at least one from among silicon oxide (SiO) and silicon nitride (SiN). The second connection terminals 630 may be provided on the bottom surface of the base chip 600. The second connection terminals 630 may be provided between the upper substrate pads 134p and a bottom surface of the base circuit layer 620. The second connection terminals 630 may be electrically connected to the integrated device or the integrated circuit of the base circuit layer 620.

The second semiconductor chip 700 may be provided on the base chip 600. A width of the second semiconductor chip 700 may be smaller than a width of the base chip 600. A thickness of the base chip 600 and the second semiconductor chip 700 of the first chip stack CS1 may be smaller than a thickness of the first semiconductor chip 300. The second semiconductor chip 700 may include a second semiconductor substrate 710, a second circuit layer 720, and a penetration via 712.

The second semiconductor substrate 710 may be a semiconductor substrate. In an embodiment, the second semiconductor substrate 710 may be formed of or include silicon (Si). A bottom surface of the second semiconductor chip 700 may be an active surface. In detail, an integrated device or integrated circuits may be formed on a bottom surface of the second semiconductor substrate 710. For example, the integrated device or the integrated circuits may include a memory circuit. That is, the second semiconductor chip 700 may be a memory chip (e.g., a DRAM, SRAM, MRAM, or FLASH memory chip).

The second semiconductor chip 700 may include the second circuit layer 720 and the penetration via 712. The second circuit layer 720 may be provided on a bottom surface (e.g., of the second semiconductor substrate 710) of the second semiconductor chip 700. The second circuit layer 720 may include the integrated device or the integrated circuit. The penetration via 712 may penetrate the second semiconductor chip 700 in a direction perpendicular to the top surface of the upper redistribution layer 130. The penetration via 712 and the second circuit layer 720 may be electrically connected to each other. Connection bumps 730 may be provided on the bottom surface of the second semiconductor chip 700. Between the base chip 600 and the second semiconductor chip 700, the connection bumps 730 may electrically connect the base chip 600 to the second semiconductor chip 700. The connection bumps 730 may be electrically connected to the integrated device or the integrated circuit of the second circuit layer 720.

In an embodiment, a plurality of second semiconductor chips 700 may be provided. For example, the second semiconductor chips 700 may be stacked on the base chip 600. The number of the second semiconductor chips 700 stacked may be, for example, 8 to 32. The connection bumps 730 may be provided between the second semiconductor chips 700, respectively. Here, the uppermost one of the second semiconductor chips 700 may not include the penetration via 712. In addition, the uppermost one of the second semiconductor chips 700 may be thinner than others of the second semiconductor chips 700 therebelow.

According to embodiments, adhesive layers may be provided between the second semiconductor chips 700. At least one of the adhesive layers may include a non-conductive film (NCF). The adhesive layers may be provided between the second semiconductor chips 700 to surround the connection bumps 730 and may be used to prevent a short circuit issue from being formed between the connection bumps 730.

The second mold layer 740 may be disposed on a top surface of the base chip 600. The second mold layer 740 may cover the top surface of the base chip 600. The second mold layer 740 may be provided to surround the second semiconductor chips 700. A top surface of the second mold layer 740 may be coplanar with a top surface of the uppermost one of the second semiconductor chips 700. The uppermost one of the second semiconductor chips 700 may be exposed to the outside of the second mold layer 740 near the top surface of the second mold layer 740. The second mold layer 740 may include an insulating polymer material. For example, the second mold layer 740 may include an epoxy molding compound (EMC).

The first chip stack CS1 may be mounted on the interposer substrate 100. For example, the first chip stack CS1 may be coupled to the upper substrate pads 134p, which are disposed on the top surface of the interposer substrate 100, through the second connection terminals 630 of the base chip 600. The second connection terminal 630 may be in contact with top surfaces of the upper substrate pads 134p and a bottom surface of the base circuit layer 620 and may electrically connect the first chip stack CS1 to the interposer substrate 100.

A second under-fill layer 640 may be provided between the interposer substrate 100 and the first chip stack CS1. The second under-fill layer 640 may be provided to fill a space between an interposer substrate 100 and the base chip 600 and to surround the upper substrate pads 134p and the second connection terminals 630.

Referring to FIG. 4, the capacitor chip 150 of the interposer substrate 100 may be vertically overlapped with the first chip stack CS1. Since the capacitor chip 150 is connected to the upper substrate pads 134p through the upper interconnection pattern 134, the first semiconductor chip 300 and the first chip stack CS1 may be electrically connected to each other. That is, the capacitor device CAP may be placed to be adjacent to the first semiconductor chip 300 and the first chip stack CS1 and may be electrically connected to the first semiconductor chip 300 and the first chip stack CS1. Thus, the power delivery efficiency and the signal transmission efficiency of the first semiconductor chip 300 and the first chip stack CS1 may be increased. Accordingly, it may be possible to improve the electrical characteristics of the semiconductor package.

FIG. 4 illustrates an example, in which the capacitor chip 150 is placed below the first chip stack CS1 and the interposer chip 140 is placed below the first semiconductor chip 300, but embodiments of the present disclosure are not limited to this example. The positions of the interposer chip 140 and the capacitor chip 150 in the interposer core structure 110 may not be limited to this example. The interposer chip 140 and the capacitor chip 150 may be horizontally spaced apart from each other in the interposer core structure 110 and may be placed regardless of vertical positions of the first semiconductor chip 300 and the first chip stack CS1. For example, at least a portion of the interposer chip 140 may be vertically overlapped with at least one from among the first semiconductor chip 300 and the first chip stack CS1. At least a portion of the capacitor chip 150 may be vertically overlapped with at least one from among the first semiconductor chip 300 and the first chip stack CS1. That is, the capacitor device CAP may be vertically overlapped with both or one of the first semiconductor chip 300 and the first chip stack CS1.

FIG. 4 illustrates an example, in which one first chip stack CS1 is provided on a top surface of the interposer substrate 100, but embodiments of the present disclosure are not limited to this example.

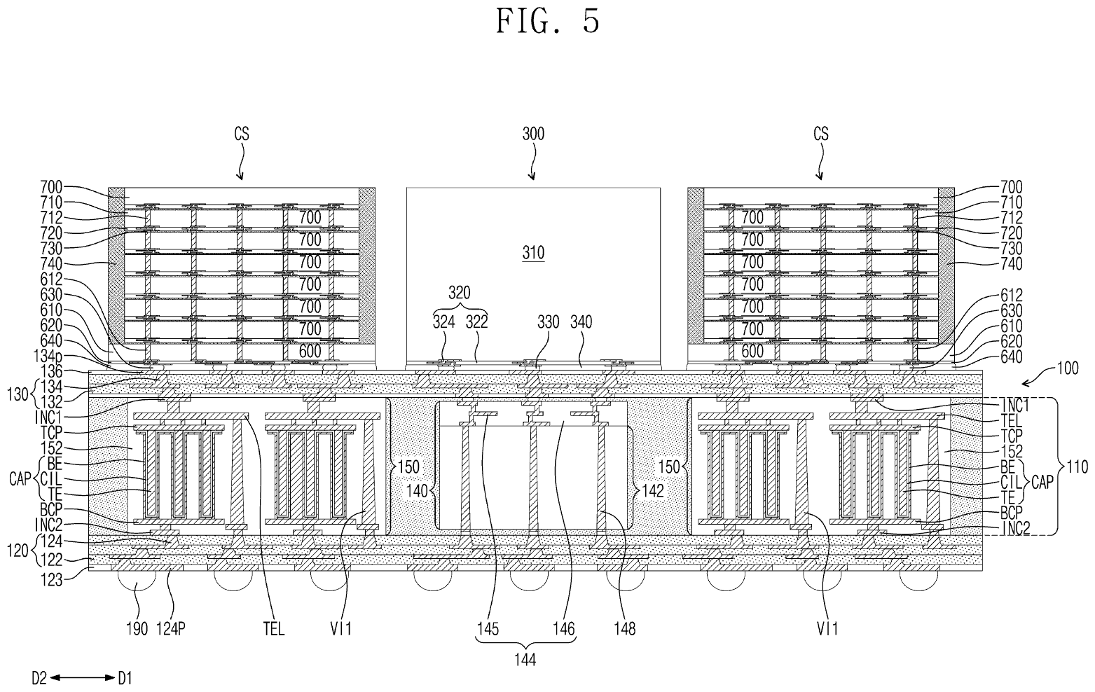

FIG. 5 is a sectional view illustrating a semiconductor package according to an embodiment of the present disclosure. Referring to FIG. 5, a plurality of chip stacks CS and a plurality of capacitor chips 150 may be provided. The chip stacks CS may be provided on the interposer substrate 100. Each of the chip stacks CS may include the base chip 600, the second semiconductor chips 700 stacked on the base chip 600, and the second mold layer 740 enclosing the second semiconductor chips 700. Each of the chip stacks CS may be provided to have the same or similar features as the features of the first chip stack CS1 described with reference to FIG. 4. The chip stacks CS may be disposed on the interposer substrate 100 to be spaced apart from each other. When viewed in a plan view, the first semiconductor chip 300 may be disposed between the chip stacks CS. For example, at least one of the chip stacks CS may be spaced apart from the first semiconductor chip 300 in each of a first direction D1 and a second direction D2, which are antiparallel to each other. In the present specification, each of the first direction D1 and the second direction D2 may be defined as a direction parallel to the top surface of the first semiconductor chip 300. The chip stacks CS may be provided to surround the first semiconductor chip 300, and the first semiconductor chip 300 may be placed between the chip stacks CS.

The capacitor chips 150 may be provided in the interposer core structure 110. For example, the capacitor chips 150 may be disposed in the interposer core structure 110, and below bottom surfaces of the chip stacks CS, respectively. When viewed in a plan view, each of the chip stacks CS may be vertically overlapped with at least a portion of a corresponding one of the capacitor chips 150. The interposer chip 140 may be disposed below the first semiconductor chip 300. When viewed in a plan view, the first semiconductor chip 300 may be vertically overlapped with at least a portion of the interposer chip 140. The interposer chip 140 and the capacitor chips 150 may be horizontally spaced apart from each other. When viewed in a plan view, the interposer chip 140 may be disposed between the capacitor chips 150. For example, at least one of the capacitor chips 150 may be spaced apart from the interposer chip 140 in each of the first direction DI and the second direction D2. The capacitor chips 150 may be provided to surround the interposer chip 140, and the interposer chip 140 may be placed between the capacitor chips 150.

However, embodiments of the present disclosure are not limited to this example. The positions of the interposer chip 140 and the capacitor chips 150 in the interposer core structure 110 may be freely changed, according to embodiments, and the capacitor chips 150 and the interposer chip 140 may be provided in the interposer core structure 110 to be spaced apart from each other. For example, at least a portion of the interposer chip 140 may be vertically overlapped with at least one from among the first semiconductor chip 300 and the chip stacks CS. At least a portion of each of the capacitor chips 150 may be vertically overlapped with at least one from among the chip stacks CS and the first semiconductor chip 300. That is, the capacitor device CAP may be vertically overlapped with at least two of the chip stacks CS and the first semiconductor chip 300 or may be vertically overlapped with one of the chip stacks CS and the first semiconductor chip 300.

Since the capacitor chips 150 are disposed below the chip stacks CS, respectively, the capacitor devices CAP may be placed near and electrically connected to the chip stacks CS. Thus, it may be possible to improve the power delivery efficiency and the signal transmission efficiency of the chip stacks CS. As a result, it may be possible to realize a semiconductor package with improved electrical characteristics.

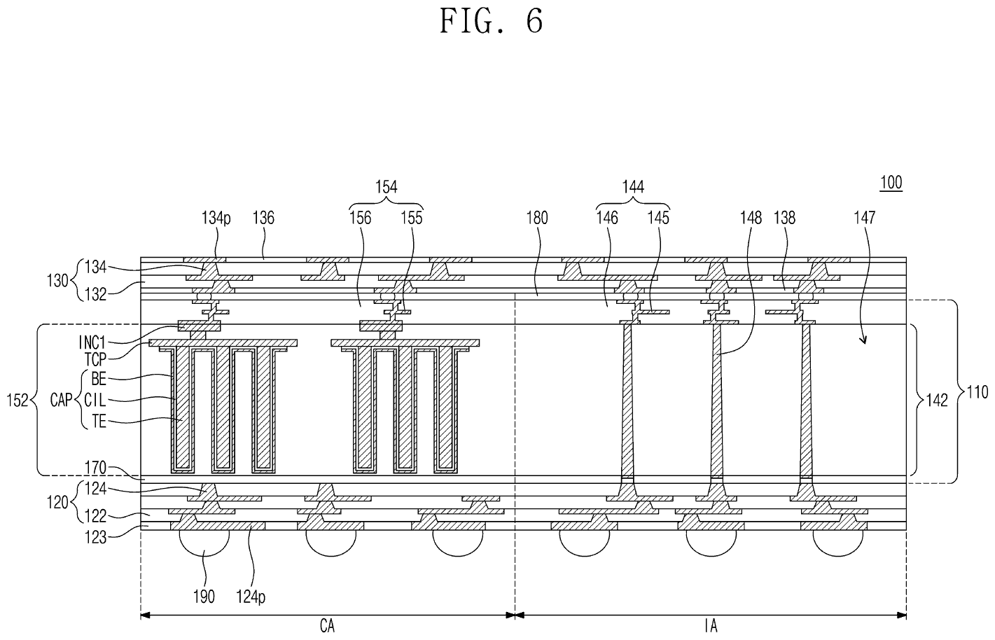

FIG. 6 is a sectional view illustrating a semiconductor package according to an embodiment of the present disclosure. Referring to FIG. 6, the interposer substrate 100 may be provided to have the structure as described with reference to FIG. 1. In an embodiment, the interposer substrate 100 may include the interposer core structure 110, the lower redistribution layer 120, and the upper redistribution layer 130. The interposer substrate 100 may include the interposer core structure 110, which has a structure substantially similar to the structure of the interposer chip 140 and the capacitor chip 150 described with reference to FIG. 1.

Here, the capacitor chip 150 may further include a capacitor interconnection layer 154, which is disposed on the top surface of the capacitor substrate 152, unlike the structure illustrated in FIG. 1. A bottom surface of the capacitor interconnection layer 154 may be in contact with the top surface of the capacitor substrate 152. The capacitor interconnection layer 154 may include a capacitor insulating pattern 156, which is provided in the capacitor interconnection layer 154, and a capacitor conductive pattern 155, which is provided in the capacitor insulating pattern 156. A portion of the capacitor conductive pattern 155 may be exposed to the outside of the capacitor insulating pattern 156 near a bottom surface of the capacitor insulating pattern 156. The portion of the capacitor conductive pattern 155, which is exposed to the outside of the capacitor insulating pattern 156 near the bottom surface of the capacitor insulating pattern 156, may be in contact with the first signal line INC1. The capacitor conductive pattern 155 may be electrically connected to the capacitor device CAP through the first signal line INC1 and the top electrode pad TCP. A portion of the capacitor conductive pattern 155 may be exposed to the outside of the capacitor insulating pattern 156 near a top surface of the capacitor insulating pattern 156. The capacitor conductive pattern 155 may be formed of a conductive material (e.g., a metallic material). For example, the capacitor conductive pattern 155 may be formed of or include copper (Cu). The capacitor insulating pattern 156 may be formed of or include an oxide material (e.g., silicon oxide (SiOₓ)).

Portions of the capacitor conductive pattern 155, which are exposed to the outside of the capacitor insulating pattern 156 near the top surface of the capacitor insulating pattern 156, may be upper capacitor pads. Exposed surfaces of the upper capacitor pads may be coplanar with the top surface of the capacitor insulating pattern 156. However, embodiments of the present disclosure are not limited to this example, and the upper interposer pads may include a protruding portion that is extended to a region on the capacitor insulating pattern 156.

That is, the interposer core structure 110 may be substantially similar to a structure, in which the capacitor chip 150 further includes the capacitor interconnection layer 154 and is connected to the interposer chip 140. Here, the interposer chip 140 and the capacitor chip 150 may have the same height (e.g., thickness) as each other. A level of the top surface of the capacitor chip 150 may be equal to a level of the top surface of the interposer chip 140, and a level of the bottom surface of the capacitor chip 150 may be equal to a level of the bottom surface of the interposer chip 140. In addition, a height (e.g., thickness) of the capacitor interconnection layer 154 may be equal to a height (e.g., thickness) of the interposer interconnection layer 144. A level of a top surface of the capacitor interconnection layer 154 may be equal to a level of a top surface of the interposer interconnection layer 144. A level of the bottom surface of the capacitor interconnection layer 154 may be equal to a level of the bottom surface of the interposer interconnection layer 144. The capacitor insulating pattern 156 and the interposer insulating pattern 146 may be formed of the same material as each other and may be provided as a single object. An interface between the capacitor insulating pattern 156 and the interposer insulating pattern 146 constituting the single object may not be visible or observable. The capacitor substrate 152 of the capacitor chip 150 may be formed of or include the same material as a material of the interposer base layer 142. The interposer base layer 142 and the capacitor substrate 152 may constitute a single object, which will be referred to as an interposer semiconductor substrate 147. The interposer semiconductor substrate 147 may be provided to have a shape without an interface between the interposer base layer 142 and the capacitor substrate 152. Since the interposer chip 140 and the capacitor chip 150 are connected to form a single object, and the interposer core structure 110 may not include the first mold layer 160.

That is, the interposer core structure 110 may include the interposer semiconductor substrate 147, and each of the interposer chip 140 and the capacitor chip 150 may be a portion of the interposer core structure 110 formed in the interposer semiconductor substrate 147. The portions may be referred to as a capacitor region CA and an interposer region IA, respectively. In the present specification, the capacitor region CA may be a region of the interposer core structure 110, in which the capacitor device CAP is provided. In addition, although the term “capacitor region” is used, it may not be limited to a region where the capacitor device CAP is placed, and a peripheral region of the interposer core structure 110, which surrounds the capacitor device CAP, may also be referred to as the capacitor region CA. In the present specification, the interposer region IA may be a region of the interposer core structure 110, in which the interposer conductive pattern 145 and the interposer vias 148 are provided. Although the term “interposer region” is used, it may not be limited to a region where the interposer conductive pattern 145 and the interposer vias 148 are placed, and the interposer region IA may be used to indicate a remaining region of the interposer core structure 110 excluding the capacitor region CA or a portion of a peripheral region of the interposer core structure 110 enclosing the interposer conductive pattern 145 and the interposer vias 148. The interposer region IA may be in contact with the capacitor region CA. For example, the interposer region IA and the capacitor region CA, which are in contact with each other, may form a boundary therebetween. Since the capacitor insulating pattern 156 and the interposer insulating pattern 146 are provided to form a single object and the interposer base layer 142 and the capacitor substrate 152 are provided to form one interposer semiconductor substrate 147, the boundary between the interposer region IA and the capacitor region CA may not be visible.

The interposer region IA of the interposer core structure 110 may be substantially similar to the interposer chip 140 described with reference to FIG. 1. For example, the interposer interconnection layer 144 and the interposer vias 148 may be disposed in the interposer region IA. The interposer region IA of the interposer core structure 110 may be electrically connected to the upper and lower redistribution layers 130 and 120. Upper interposer pads and upper interposer connection terminals may be disposed on the top surface of the interposer core structure 110. An end of each of the upper interposer connection terminals may be in contact with a corresponding one of the upper interposer pads. An opposite end of each of the upper interposer connection terminals may be in contact with a corresponding one of the first substrate pads. The interposer region IA may be electrically connected to the upper redistribution layer 130 through the upper interposer connection terminals. Lower interposer pads and lower interposer connection terminals may be disposed on a bottom surface of the interposer core structure 110. An end of each of the lower interposer connection terminals may be in contact with a corresponding one of the lower interposer pads. An opposite end of the lower interposer connection terminal may be in contact with the lower interconnection pattern 124. The interposer region IA may be electrically connected to the lower redistribution layer 120 through lower interposer connection terminals.

The capacitor region CA of the interposer core structure 110 may further include the capacitor interconnection layer 154, which is disposed on the top surface of the capacitor substrate 152, compared to the structure of FIG. 1. In an embodiment, the first signal line INC1, the top electrode pad TCP, and the capacitor device CAP may be disposed in the capacitor region CA. In addition, a plurality of first signal lines INC1, a plurality of top electrode pads TCP, and a plurality of capacitor devices CAP may be provided, according to embodiments. Hereinafter, for the sake of brevity, the description that follows will refer to an example in which one capacitor device CAP is provided in the capacitor region CA, but the description may also be applied to other capacitor devices CAPs.

In the capacitor region CA, upper chip connection terminals may be provided on the top surface of the capacitor interconnection layer 154. The upper chip connection terminals may include solder balls or solder bumps. The upper chip connection terminals may be disposed between the capacitor region CA and the upper redistribution layer 130. Ends of the upper chip connection terminals may be in contact with the capacitor conductive patterns 155, which are exposed to the outside of the capacitor interconnection layer 154 near the top surface of the capacitor interconnection layer 154. Opposite ends of the upper chip connection terminals may be in contact with the first substrate pads. The capacitor chip 150 may be electrically connected to the upper redistribution layer 130 using the upper chip connection terminals. The upper redistribution layer 130 may be electrically connected to the capacitor device CAP through the upper chip connection terminals, the capacitor conductive pattern 155, the first signal line INC1, and the top electrode pad TCP.

A level of a bottom surface of the bottom electrode BE of the capacitor device CAP may be higher than a level of a bottom surface of the interposer semiconductor substrate 147. That is, the bottom surface of the bottom electrode BE of the capacitor device CAP may be spaced apart from the lower redistribution layer 120. However, embodiments of the present disclosure are not limited to this example. According to embodiments, the bottom electrode pad BCP, the second signal line INC2, and the lower chip connection terminals may be provided on the bottom surface of the bottom electrode BE (refer to FIG. 2). The bottom electrode pad BCP, the second signal line INC2, and the lower chip connection terminals may be respectively provided to have the same or similar features as the features described with reference to FIG. 2. For example, the bottom electrode pad BCP may be disposed on the bottom surface of the bottom electrode BE. The bottom electrode BE may be electrically connected to the bottom electrode pad BCP. The second signal line INC2 may be provided on the bottom surface of the bottom electrode pad BCP. The second signal line INC2 may be electrically connected to the bottom electrode pad BCP through a via plug. The bottom surface of the second signal line INC2 may be coplanar with the bottom surface of the interposer semiconductor substrate 147. The second signal line INC2 may be electrically connected to the lower redistribution layer 120. Lower chip connection terminals (e.g., solder balls or solder bumps) may be provided on a bottom surface of the capacitor region CA. The lower chip connection terminals may be provided between the top surface of the lower redistribution layer 120 and the bottom surface of the capacitor region CA to electrically connect the lower redistribution layer 120 to the capacitor region CA. The lower chip connection terminals may be electrically connected to the capacitor device CAP in the capacitor region CA through the second signal line INC2.

A third under-fill layer 170 may be provided on the bottom surface of the interposer core structure 110. The third under-fill layer 170 may be provided to surround the bottom surface of the interposer core structure 110 and to surround the lower interposer connection terminals. The third under-fill layer 170 may fill a region between the interposer core structure 110 and the lower redistribution layer 120. A fourth under-fill layer 180 may be provided on the top surface of the interposer core structure 110. The fourth under-fill layer 180 may be provided to cover the top surface of the interposer core structure 110 and to surround upper chip connection terminals and upper interposer connection terminals. The fourth under-fill layer 180 may be provided to fill a space between the interposer core structure 110 and the upper redistribution layer 130.

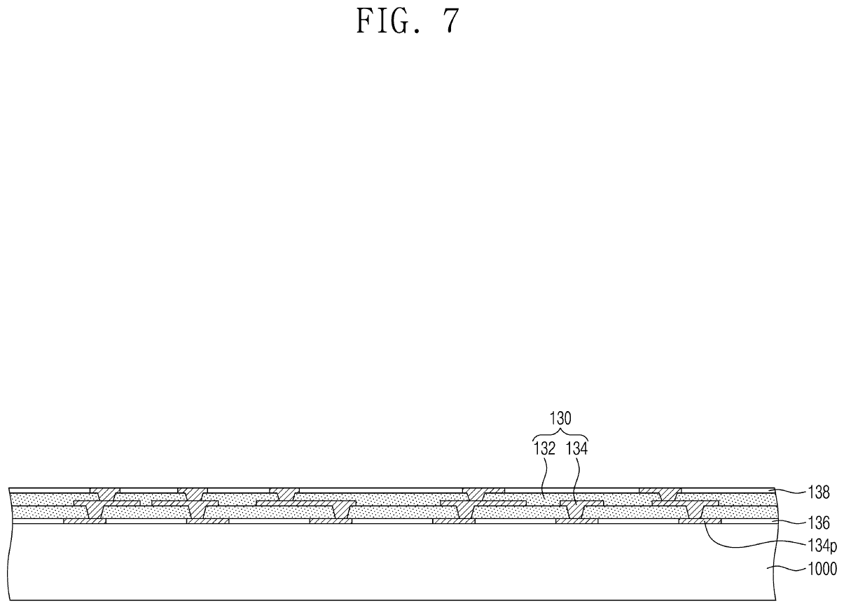

FIGS. 7 to 10 are sectional views illustrating a method of fabricating a semiconductor package, according to an embodiment of the present disclosure. Referring to FIG. 7, a first carrier substrate 1000 may be provided. The upper redistribution layer 130 may be formed on the first carrier substrate 1000. For example, the upper substrate protection layer 136 may be formed on a top surface of the first carrier substrate 1000. A conductive layer may be formed on the upper substrate protection layer 136 and may be patterned to form the upper substrate pads 134p. The upper substrate pads 134p may be portions of the lowermost one of the upper interconnection patterns 134. An insulating layer may be formed on the upper substrate protection layer 136 and may be patterned to form one upper insulating pattern 132. An upper interconnection layer may be formed by forming a conductive layer on the upper insulating pattern 132 and patterning the conductive layer to form the upper interconnection pattern 134. A process of forming the upper interconnection layer may be repeated to form the upper redistribution layer 130 with the upper interconnection layers. The upper interconnection pattern 134, which is provided in the uppermost one of the upper interconnection layers, may be first substrate pads. Thereafter, the first substrate protection layer 138 may be formed on the upper interconnection layers to cover the first substrate pads.

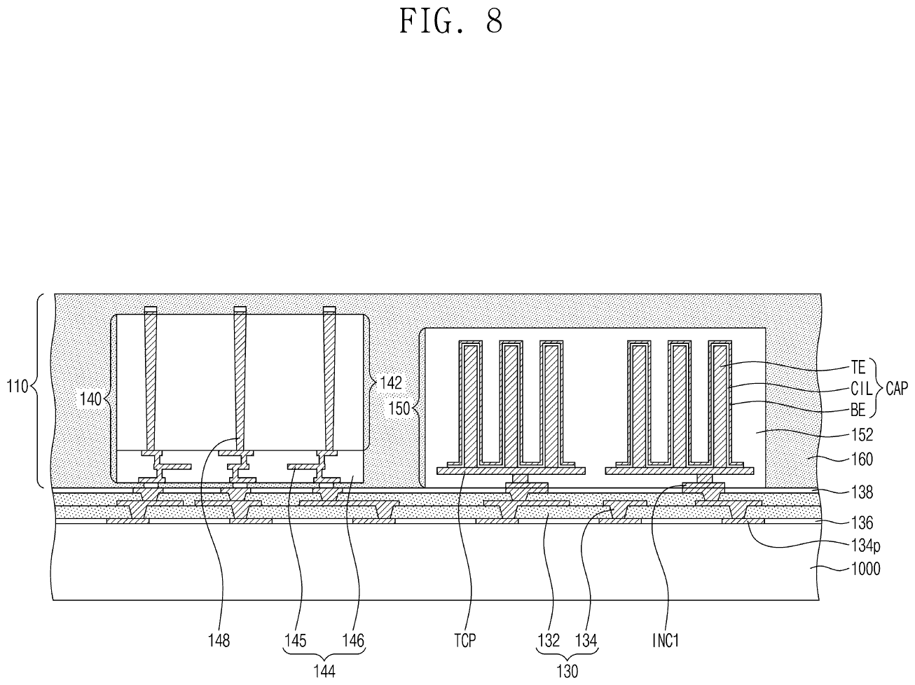

Referring to FIG. 8, the interposer chip 140 and the capacitor chip 150 may be mounted on the structure of FIG. 7. The interposer chip 140 and the capacitor chip 150 may be provided to have the same or similar features as the features in the embodiment of FIG. 1. For example, the interposer chip 140 may include the interposer base layer 142 and the interposer interconnection layer 144. The capacitor chip 150 may include the capacitor substrate 152, the capacitor device CAP, and the first signal lines INC1. The interposer interconnection layer 144 of the interposer chip 140 may be disposed to face the upper redistribution layer 130. Thereafter, the interposer chip 140 may be mounted on the upper redistribution layer 130 through upper interposer connection terminals. The upper interposer connection terminals may connect the upper interposer pads to the first substrate pads. The capacitor chip 150 may be disposed such that the first signal lines INC1 are in contact with the top surface of the upper redistribution layer 130. The capacitor chip 150 may be disposed to be horizontally spaced apart from the interposer chip 140.

The first mold layer 160 may be provided to surround the interposer chip 140 and the capacitor chip 150. The first mold layer 160 may be provided to fill spaces between the upper redistribution layer 130 and the interposer chip 140, between the upper redistribution layer 130 and the capacitor chip 150, and between the interposer chips 140 and the capacitor chips 150. For example, the first mold layer 160 may be formed by coating and curing an insulating material. The first mold layer 160 may cover the interposer chip 140 and the capacitor chip 150. The first mold layer 160, the interposer chip 140, and the capacitor chip 150 may constitute the interposer core structure 110.

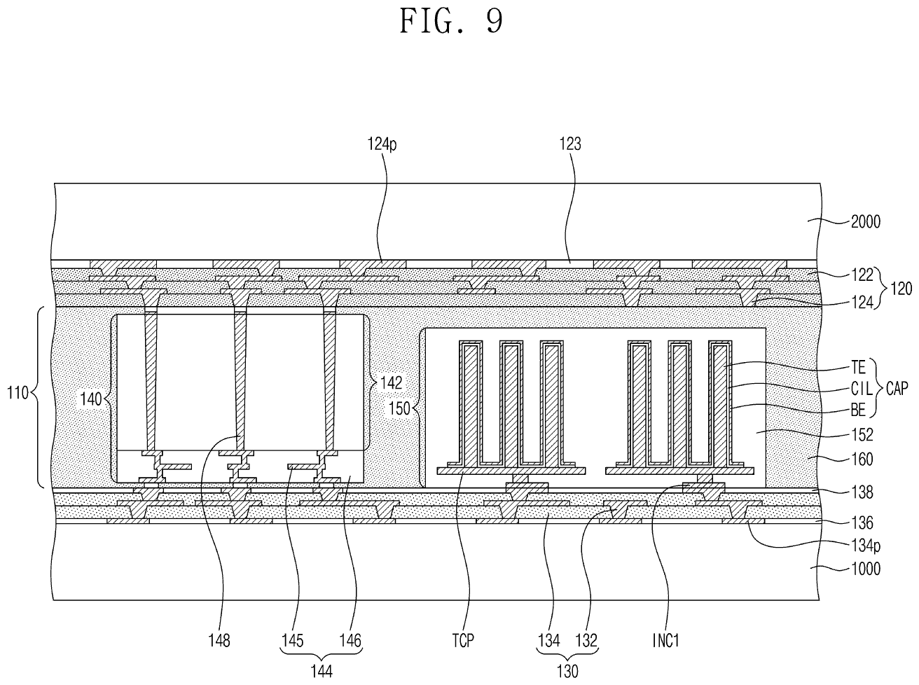

Referring to FIG. 9, the lower redistribution layer 120 may be formed on the top surface of the first mold layer 160. A grinding process may be performed on the top surface of the first mold layer 160. As a result of the grinding process, top surfaces of lower interposer connection terminals, which are disposed on the top surface of the interposer chip 140, may be exposed to the outside of the interposer chip 140. A grinded top surface of the first mold layer 160 may be coplanar with the top surface of the lower interposer connection terminals. An insulating layer may be formed on the grinded top surface of the first mold layer 160. The insulating layer may be patterned to form one lower insulating pattern 122. A lower interconnection layer may be formed by forming a conductive layer on the lower insulating pattern 122 and patterning the conductive layer to form the lower interconnection pattern 124. A process of forming the lower interconnection layer may be repeated to form the lower redistribution layer 120 having a plurality of lower interconnection layers. The lower interconnection pattern 124, which is provided in the uppermost one of the lower interconnection layers, may be the lower substrate pads 124p. Next, the lower substrate protection layer 123 may be formed on the lower interconnection layers to cover the lower substrate pads 124p. A second carrier substrate 2000 may be provided on the top surface of the lower redistribution layer 120.

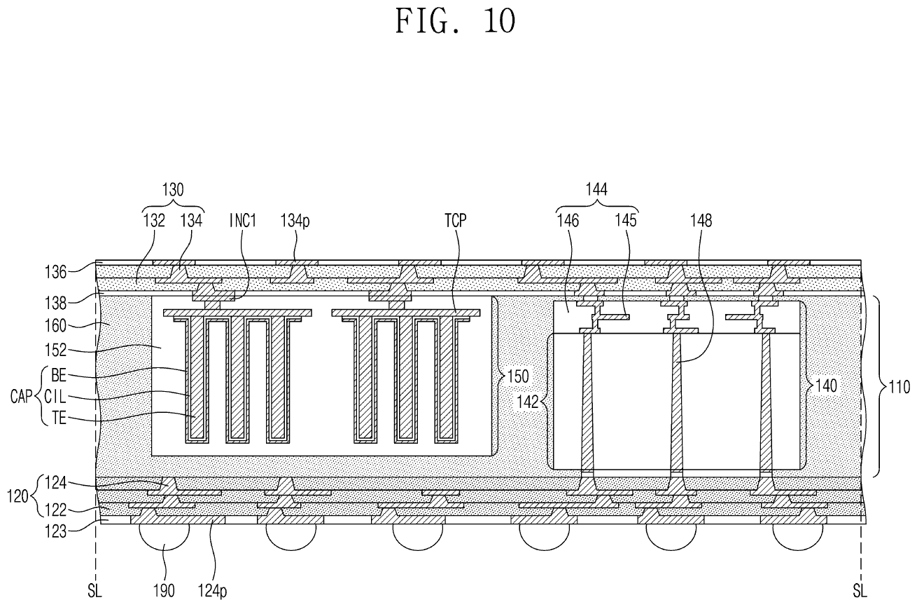

Referring to FIG. 10, the structure of FIG. 9 may be inverted. Thus, the upper redistribution layer 130 may be placed on the top surface of the interposer core structure 110. The lower redistribution layer 120 may be placed on the bottom surface of the interposer core structure 110. Thereafter, the first carrier substrate 1000 may be removed to expose the top surface of the upper redistribution layer 130 to the outside. The second carrier substrate 2000 may be removed, and then, the outer terminals 190 may be disposed on the bottom surface of the lower redistribution layer 120. The outer terminals 190 may be provided on bottom surfaces of the lower substrate pads 124p, which protrude to a region below the bottom surface of the lower redistribution layer 120. For example, the outer terminals 190 (e.g., solder balls or solder bumps) may be attached to the bottom surface of the lower substrate pads 124p. Thereafter, a sawing process may be performed along a sawing line SL to form a single substrate. Referring back to FIG. 1, the substrate, which is cut by the sawing process, may correspond to the interposer substrate 100 of FIG. 1. As a result of the afore-described process, the semiconductor package may have the same structure as the structure of FIG. 1.

In a semiconductor package according to an embodiment of the present disclosure, a passive device may be placed at an intermediate level of the semiconductor package and may be placed near and connected to a semiconductor chip, which is disposed on a substrate. Thus, it may be possible to improve the electrical characteristics of the semiconductor package.

In a semiconductor package according to an embodiment of the present disclosure, a passive device may be placed at an intermediate level of the semiconductor package, and in this case, it may be possible to omit an additionally passive device and consequently to reduce a size of the semiconductor package.

While non-limiting example embodiments of the present disclosure have been particularly shown and described, it will be understood by one of ordinary skill in the art that variations in form and detail may be made therein without departing from the spirit and scope of the present disclosure.

What is claimed is:

1. A semiconductor package, comprising:
a lower redistribution layer;
a capacitor chip on the lower redistribution layer;
an interposer chip on the lower redistribution layer, horizontally spaced apart from the capacitor chip, and connected to the lower redistribution layer;
a mold layer surrounding the capacitor chip and the interposer chip; and
an upper redistribution layer on a top surface of the mold layer and connected to the capacitor chip and the interposer chip,
wherein the capacitor chip comprises a capacitor substrate and a capacitor device in
the capacitor substrate, and
wherein the capacitor device comprises:
a top electrode pad;
top electrodes on a bottom surface of the top electrode pad, a capacitor dielectric layer on the top electrodes with a uniform thickness; and
a bottom electrode on the capacitor dielectric layer such as to commonly cover the top electrodes.

2. The semiconductor package of claim 1, wherein the interposer chip comprises a penetration via that vertically penetrates the interposer chip, and
wherein the interposer chip is electrically connected to the lower redistribution layer by the penetration via.

3. The semiconductor package of claim 1, further comprising a vertical connection conductor that is horizontally spaced apart from the capacitor chip and the interposer chip, vertically penetrates the mold layer, and connects the lower redistribution layer to the upper redistribution layer.

4. The semiconductor package of claim 1, further comprising a connection substrate between the lower redistribution layer and the upper redistribution layer, wherein the connection substrate comprises an opening that vertically penetrates the connection substrate,
wherein the capacitor chip and the interposer chip are in the opening of the connection substrate,
wherein the mold layer is in the opening and fills spaces between the capacitor chip and the connection substrate and between the interposer chip and the connection substrate, and
wherein the connection substrate comprises a connection interconnection pattern.

5. The semiconductor package of claim 1, wherein a thickness of the capacitor chip is smaller than a thickness of the interposer chip,
wherein a bottom surface of the capacitor chip is vertically spaced apart from the lower redistribution layer, and
wherein the mold layer is on the bottom surface of the capacitor chip.

6. The semiconductor package of claim 1, wherein each of the capacitor chip and the interposer chip is mounted on the upper redistribution layer by connection terminals that are between the capacitor chip and the upper redistribution layer and between the interposer chip and the upper redistribution layer, and
wherein the connection terminals comprise solder balls or solder bumps.

7. The semiconductor package of claim 1, wherein the capacitor device further comprises a bottom electrode pad on a bottom surface of the bottom electrode,
wherein the top electrode pad is coupled to the upper redistribution layer, and
wherein the bottom electrode pad is coupled to the lower redistribution layer.

8. A semiconductor package, comprising:
an interposer substrate; and
at least one semiconductor chip on the interposer substrate,
wherein the interposer substrate comprises:
a lower redistribution layer comprising a lower insulating pattern;
a lower interconnection pattern in the lower insulating pattern;
an upper redistribution layer on the lower redistribution layer, the upper redistribution layer comprising an upper insulating pattern and an upper interconnection pattern in the upper insulating pattern; and
an interposer core structure between the lower redistribution layer and the upper redistribution layer,
wherein the interposer core structure comprises a capacitor chip and an interposer chip,
wherein the capacitor chip comprises:
a first electrode;
a second electrode spaced apart from the first electrode; and
a dielectric layer between the first electrode and the second electrode,
wherein a top surface of the capacitor chip is exposed to an outside towards a top surface of the interposer core structure and is connected to the upper redistribution layer, and
wherein a bottom surface of the capacitor chip is exposed to the outside towards a bottom surface of the interposer core structure and is connected to the lower redistribution layer.

9. The semiconductor package of claim 8, wherein the capacitor chip further comprises:
a top electrode pad on a top surface of the first electrode; and
a bottom electrode pad on a bottom surface of the second electrode,
wherein the dielectric layer is on bottom and side surfaces of the first electrode with a uniform thickness,
wherein the second electrode is on the dielectric layer such that the dielectric layer is in between the first electrode and the second electrode,
wherein the top electrode pad is exposed to the outside towards the top surface of the capacitor chip and is coupled to the upper redistribution layer, and
wherein the bottom electrode pad is exposed to the outside towards the bottom surface of the capacitor chip and is coupled to the lower redistribution layer.

10. The semiconductor package of claim 8, wherein the interposer chip further comprises at least one penetration via that vertically penetrates the interposer chip.

11. The semiconductor package of claim 8, further comprising:
a mold layer surrounding the capacitor chip and the interposer chip; and
at least one vertical connection conductor, which is horizontally spaced apart from the capacitor chip and the interposer chip and is provided to vertically penetrate the mold layer and to connect the lower redistribution layer to the upper redistribution layer,
wherein the capacitor chip and the interposer chip are horizontally spaced apart from each other, and
wherein the mold layer fills a space between the capacitor chip and the interposer chip.

12. The semiconductor package of claim 9, wherein the lower redistribution layer further comprises a lower seed pattern that is exposed to the outside towards a top surface of the lower interconnection pattern,
wherein the upper redistribution layer further comprises an upper seed pattern that is exposed to the outside towards a bottom surface of the upper interconnection pattern,
wherein the bottom electrode pad and the lower seed pattern are in contact with each other and are integrally formed with each other, and
wherein the top electrode pad and the upper seed pattern are in contact with each other and are integrally formed with each other.

13. The semiconductor package of claim 8, wherein the at least one semiconductor chip is a plurality of semiconductor chips,
wherein the plurality of semiconductor chips comprises:
a logic chip; and
a chip stack horizontally spaced apart from the logic chip, and
wherein the capacitor chip is below the chip stack.

14. The semiconductor package of claim 8, wherein the interposer core structure further comprises a semiconductor substrate, and
wherein the capacitor chip and the interposer chip are portions of the semiconductor substrate.

15. A semiconductor package, comprising:
an interposer substrate;
an outer connection terminal on a bottom surface of the interposer substrate;
a logic chip on the interposer substrate; and
a chip stack on the interposer substrate and spaced apart from the logic chip,
wherein the interposer substrate comprises:
a lower redistribution layer;
an upper redistribution layer on the lower redistribution layer;
a capacitor chip between the lower redistribution layer and the upper redistribution layer;
an interposer chip between the lower redistribution layer and the upper redistribution layer and horizontally spaced apart from the capacitor chip; and
a mold layer surrounding the capacitor chip and the interposer chip, wherein the interposer chip comprises:
at least one penetration via that penetrates the interposer chip and connects the interposer chip to the lower redistribution layer;
an upper connection terminal on a top surface of the interposer chip and connects the interposer chip to the upper redistribution layer; and
a lower connection terminal on a bottom surface of the interposer chip and connects the interposer chip to the lower redistribution layer,
wherein the capacitor chip comprises at least one capacitor device, and
wherein the capacitor chip is coupled to the lower redistribution layer and the upper redistribution layer.

16. The semiconductor package of claim 15, wherein the at least one capacitor device comprises a top electrode, a bottom electrode on the top electrode, and a capacitor dielectric layer between the bottom electrode and the top electrode.

17. The semiconductor package of claim 16, wherein the at least one capacitor device is a plurality of capacitor devices,
wherein the capacitor chip further comprises:
top electrode lines on a top surface of the plurality of capacitor devices and electrically connected to the top electrode of at least one of the plurality of capacitor devices; and
first vias extending from the top electrode lines such as to penetrate the capacitor chip, and
wherein the top electrode lines are electrically connected to the lower redistribution layer by the first vias.

18. The semiconductor package of claim 15, further comprising a connection substrate that is between the lower redistribution layer and the upper redistribution layer and includes an opening that penetrates the connection substrate,
wherein the capacitor chip and the interposer chip in the opening of the connection substrate,
wherein the mold layer fills spaces between the capacitor chip and the connection substrate and between the interposer chip and the connection substrate, in the opening, and
wherein the connection substrate comprises a connection interconnection pattern.

19. The semiconductor package of claim 15, further comprising at least one vertical connection conductor that is horizontally spaced apart from the capacitor chip and the interposer chip, and vertically penetrates the mold layer such as to connect the lower redistribution layer to the upper redistribution layer.

20. The semiconductor package of claim 15, wherein the interposer chip is below the logic chip, and
wherein the capacitor chip is below the chip stack.
